(19) United States
(12) Patent Application Publication
(10) Pub. No.: US 2024/0317580 A1
(43) Pub. Date: Sep. 26, 2024

(54) MEMS DEVICE AND MANUFACTURING METHOD OF MEMS DEVICE

(71) Applicant: Murata Manufacturing Co., Ltd., Nagaokakyo-shi (JP)

(72) Inventors: Fumiya KUROKAWA, Nagaokakyo-shi (JP); Yasuhiro AIDA, Nagaokakyo-shi (JP)

(21) Appl. No.: 18/736,603

(22) Filed: Jun. 7, 2024

Related U.S. Application Data
(63) Continuation of application No. PCT/JP2022/044768, filed on Dec. 5, 2022.

(30) Foreign Application Priority Data
Dec. 23, 2021 (JP) 2021-209528

(51) Int. Cl. B81C 1/00; B81B 7/00

(52) U.S. Cl. CPC B81C 1/00301; B81B 7/007; B81B 2201/0235; B81B 2201/0242; B81B 2201/0264; B81B 2201/0271; B81B 2207/07; B81B 2207/096; B81C 2203/0109

(57) ABSTRACT

A MEMS device includes a first substrate having a MEMS structure, a second substrate opposing the first substrate with an interval therebetween in an opposing direction, a first joint portion that includes a eutectic layer including as a main material, a eutectic alloy of plural types of metal, that is provided between the first and second substrates and surrounds the MEMS structure as viewed in the opposing direction, and that is joined to the first and second substrates, and a contact layer that is provided between the first and second substrates and is in contact with the first and second substrates. The contact layer includes a portion of the plural types of metal included in the first joint portion.

### CROSS REFERENCE TO RELATED APPLICATIONS

This application claims the benefit of priority to Japanese Patent Application No. 2021-209528, filed on Dec. 23, 2021, and is a Continuation Application of PCT Application No. PCT/JP2022/044768, filed on Dec. 5, 2022. The entire contents of each application are hereby incorporated herein by reference.

### BACKGROUND OF THE INVENTION

### 1. Field of the Invention

The present invention relates to MEMS devices and manufacturing methods of MEMS devices.

### 2. Description of the Related Art

MEMS devices, which are manufactured by using microelectromechanical systems (MEMS) technology, are known. A MEMS device is formed by joining, to a first substrate, a second substrate, the first substrate including a MEMS structure, for example, such as a resonator.

For example, Japanese Unexamined Patent Application Publication No. 2013-125912 discloses an electronic component as an example of MEMS devices.

In the electronic component disclosed in Japanese Unexamined Patent Application Publication No. 2013-125912, a base substrate (a first substrate) and a cover substrate (a second substrate) form a casing including an internal space. The casing accommodates a MEMS structure. Metal films are individually defined in the upper surface of the first substrate and the lower surface of the second substrate. The metal film in the first substrate and the metal film in the second substrate undergo a metal eutectic reaction to join the first and second substrates.

In the electronic component disclosed in Japanese Unexamined Patent Application Publication No. 2013-125912, an insulating film is defined in the lower surface of the second substrate. In the process of joining the first and second substrates, the insulating film comes into contact with the upper surface of the first substrate. This makes variations in interval between the first and second substrates smaller.

The first and second substrates are joined at high temperature under high load to cause the metal films to undergo a metal eutectic reaction. This could deform the insulating film. Deformation of the insulating film increases variations in interval between the first and second substrates.

### SUMMARY OF THE INVENTION

Example embodiments of the present invention provide MEMS devices in each of which variations in interval between the first and second substrates can be reduced.

A MEMS device according to an example embodiment of the present invention includes a first substrate including a MEMS structure, a second substrate opposing the first substrate with an interval therebetween in an opposing direction, a first joint portion including a eutectic layer including as a main material, a eutectic alloy of a plurality of types of metal, provided between the first substrate and the second substrate and surrounding the MEMS structure as viewed in the opposing direction, and joined to the first substrate and the second substrate, and a contact layer between the first substrate and the second substrate, directly or indirectly in contact with the first substrate, and directly or indirectly in contact with the second substrate. The contact layer includes a portion of the plurality of types of metal included in the first joint portion.

According to example embodiments of the present invention, it is possible to make variations in interval between the first and second substrates smaller.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a plan view of a MEMS device according to a first example embodiment of the present invention.

FIG. 2 is a cross-sectional view of an A-A cross section of FIG. 1.

FIG. 3 is a cross-sectional view when first and third metal layers are provided on a first substrate in a manufacturing process of the MEMS device according to the first example embodiment of the present invention.

FIG. 4 is a cross-sectional view when contact layers are provided on the first substrate in the manufacturing process of the MEMS device according to the first example embodiment of the present invention.

FIG. 5 is a cross-sectional view when second and fourth metal layers are provided on a second substrate in the manufacturing process of the MEMS device according to the first example embodiment of the present invention.

FIG. 6 is a cross-sectional view when insulating layers are provided on the second substrate in the manufacturing process of the MEMS device according to the first example embodiment of the present invention.

FIG. 7 is a cross-sectional view of a cross section corresponding to the A-A cross section of FIG. 1 in a MEMS device according to a second example embodiment of the present invention.

FIG. 8 is a cross-sectional view of a cross section corresponding to the A-A cross section of FIG. 1 in a MEMS device according to a third example embodiment of the present invention.

FIG. 9 is a plan view of a MEMS device according to a fourth example embodiment of the present invention.

FIG. 10 is a plan view of another MEMS device according to the fourth example embodiment of the present invention.

FIG. 11 is a plan view of still another MEMS device according to the fourth example embodiment of the present invention.

FIG. 12 is a plan view of a MEMS device according to a fifth example embodiment of the present invention.

FIG. 13 is a cross-sectional view of a B-B cross section of FIG. 12.

FIG. 14 is a plan view of a MEMS device according to a sixth example embodiment of the present invention.

FIG. 15 is a plan view of another MEMS device according to the sixth example embodiment of the present invention.

FIG. 16 is a plan view of still another MEMS device according to the sixth example embodiment of the present invention.

FIG. 17 is a plan view of a MEMS device according to a seventh example embodiment of the present invention.

FIG. 18 is a plan view of another MEMS device according to the seventh example embodiment of the present invention.

FIG. 19 is a plan view of still another MEMS device according to the seventh example embodiment of the present invention.

FIG. 20 is a plan view of a MEMS device according to an eighth example embodiment of the present invention.

FIG. 21 is a cross-sectional view of the contact layer and the vicinity thereof in a MEMS device according to a ninth example embodiment of the present invention.

FIG. 22 is a cross-sectional view of the contact layer and the vicinity thereof in another MEMS device according to the ninth example embodiment of the present invention.

FIG. 23 is a cross-sectional view of the contact layer and the vicinity thereof in still another MEMS device according to the ninth example embodiment of the present invention.

### DETAILED DESCRIPTION OF THE EXAMPLE EMBODIMENTS

A MEMS device according to an example embodiment of the present invention includes a first substrate including a MEMS structure, a second substrate opposing the first substrate with an interval therebetween in an opposing direction, a first joint portion that includes a eutectic layer including, as a main material, a eutectic alloy of a plurality of types of metal, that is provided between the first substrate and the second substrate and surrounds the MEMS structure as viewed in the opposing direction, and that is joined to the first substrate and the second substrate, and a contact layer that is provided between the first substrate and the second substrate, that is directly or indirectly in contact with the first substrate and is directly or indirectly in contact with the second substrate. The contact layer includes a portion of the plurality of types of metal included in the first joint portion.

According to this configuration, the first substrate, the second substrate, and the first joint portion define a space for the MEMS structure to vibrate.

According to this configuration, the distance between the first and second substrates can be controlled so as to be equal or substantially equal to the height of the contact layer by the contact layer coming into contact with the first and second substrates in the manufacturing process of the MEMS device.

The temperature at which the plurality of types of metal undergo a metal eutectic reaction is lower than the melting point of each of the plurality of types of metal. The plurality of types of metal included in the first joint portion undergo a metal eutectic reaction at a temperature lower than the melting point of each of the plurality of types of metal in the manufacturing process of the MEMS device. Herein, according to this configuration, the contact layer includes a portion of the same plurality of types of metal as the first joint portion. The melting point of the metal included in the contact layer is therefore higher than the temperature at which the plurality of types of metal included in the first joint portion undergo a metal eutectic reaction in the manufacturing process of the MEMS device. This means that the contact layer can be chemically stabilized in a high-temperature and high-load condition where the metals undergo a metal eutectic reaction. It is therefore possible to reduce deformation of the contact layer in the manufacturing process of the MEMS device, thus making the variations in interval between the first and second substrates smaller.

According to this configuration, the contact layer includes a portion of the same plurality of types of metal as the first joint portion. Therefore, even if the metal included in the contact layer is mixed into the first joint portion in the manufacturing process of the MEMS device, its influence on the first joint portion can be made smaller.

In the MEMS device, the length of the first joint portion in the opposing direction may be greater than or equal to the length of the contact layer in the opposing direction.

According to this configuration, the length of the first joint portion in the opposing direction is greater than or equal to the length of the contact layer in the opposing direction. This allows for application of high load to the first joint portion in the manufacturing process of the MEMS device.

The MEMS device according to an example embodiment of the present invention may further include a second joint portion that includes a eutectic layer including as a main material, the eutectic alloy of the plurality of types of metal, that is positioned inside the first joint portion as viewed in the opposing direction between the first substrate and the second substrate, and that is joined to the first substrate and the second substrate.

According to this configuration, the second joint portion is positioned inside the first joint portion as viewed in the opposing direction. The second joint portion is positioned closer to the MEMS structure than in the configuration in which the second joint portion is positioned outside the first joint portion as viewed in the opposing direction. Therefore, the second joint portion and the MEMS structure can be electrically coupled with shorter wiring.

In the MEMS device, the second joint portion may include at least a portion of materials defining the first substrate and the second substrate.

According to this configuration, the material included in the second joint portion diffuses into at least one of the first substrate and the second substrate. This allows the second joint portion to maintain ohmic contact with at least one of the first substrate and the second substrate. Therefore, when the second joint portion is used as wiring, the second joint portion and at least one of the first substrate and the second substrate can be electrically coupled with a high degree of reliability.

The MEMS device may further include a first insulating layer that is provided on the contact layer and is electrically insulated.

An unintended electrical coupling between the first and second substrates through the contact layer creates unwanted wiring in the MEMS device. In this case, stray capacitance could be produced, for example, between the unwanted wiring and a via conductor or an electrode pad defined in the second substrate. The stray capacitance could deteriorate the electric characteristics of the MEMS device. Furthermore, the unwanted wiring could increase the power consumption of the MEMS device.

According to this configuration, the first insulating layer prevents electrical coupling between the first and second substrates through the contact layer. It is therefore possible to prevent the formation of stray capacitance and increase in power consumption described above.

In the MEMS device, the first insulating layer may be embedded in at least one of the first substrate and the second substrate.

According to this configuration, the contact surface of the first insulating layer with the contact layer can be flush with the first or second substrate in which the first insulating layer is embedded. Therefore, the control of the interval between the first and second substrates by the contact layer can be easily performed with high accuracy.

The MEMS device may further include a second insulating layer that is provided on the first joint portion and is electrically insulated, the second insulating layer may be provided at the same position or at substantially the same position in the opposing direction as the first insulating layer.

If an insulating layer is provided only on the contact layer, among the contact layer and the first joint portion, there could be a height difference between the first joint portion and the contact layer equivalent to the height of the insulating layer in the manufacturing process of the MEMS device. According to the aforementioned configuration, the insulating layers are provided on both of the first joint portion and the contact layer. This can make the height difference between the first joint portion and the contact layer smaller in the manufacturing process of the MEMS device. Therefore, the control of the interval between the first and second substrates by the formation of the contact layer can be easily performed with high accuracy.

In the MEMS device, the first insulating layer and the second insulating layer may be embedded in at least one of the first substrate and the second substrate.

According to this configuration, the contact surface between the second insulating layer and the first joint portion and the contact surface between the first insulating layer and the contact layer can be flush with the first or second substrate in which the insulating layers are embedded. Therefore, the control of the interval between the first and second substrates by the contact layer can be easily performed with high accuracy.

In the MEMS device, a cavity may be provided in an interface between the first insulating layer and the contact layer.

If no cavity is provided in the interface between the first insulating layer and the contact layer, the first insulating layer and the contact layer are in contact over a large area. The contact layer is therefore more likely to be crushed and deformed by the first insulating layer at high temperature under high load in the manufacturing process of the MEMS device. According to the aforementioned configuration, however, the cavity is provided in the interface between the first insulating layer and the contact layer, so that the first insulating layer and the contact layer are in contact over a small area. Therefore, the contact layer is less likely to be deformed at high temperature under high load in the manufacturing process of the MEMS device.

In the MEMS device, the contact layer may be positioned inside the first joint portion as viewed in the opposing direction.

According to this configuration, the contact layer is positioned inside the first joint portion as viewed in the opposing direction. The MEMS device can be reduced in size compared to a configuration in which the contact layer is positioned outside the first joint portion as viewed in the opposing direction.

In the MEMS device, the MEMS structure may include a fixed portion fixed to the first substrate, and a moving portion flexible relative to the first substrate. The contact layer may be in contact with the fixed portion as viewed in the opposing direction.

According to this configuration, the contact layer is in contact with the MEMS structure. The second substrate therefore does not need to include a region for the contact layer to come into contact with, other than the MEMS structure. This can reduce the MEMS device in size.

According to the aforementioned configuration, the contact layer is in contact with the fixed portion of the MEMS structure. The contact layer therefore cannot inhibit the vibration of the MEMS structure.

In the MEMS device, the region surrounded by the first joint portion may be rotationally symmetric as viewed in the opposing direction, and as viewed in the opposing direction, the distance between the center of rotational symmetry of the region surrounded by the first joint portion and the contact layer may be shorter than the distance between the first joint portion and the contact layer.

When the first joint portion is distant from the center of rotational symmetry of the region surrounded by the first joint portion as viewed in the opposing direction, the first and second substrates are more likely to bend at the center.

According to the aforementioned configurations, the contact layer is positioned adjacent to the center of rotational symmetry of the region surrounded by the first joint portion as viewed in the opposing direction. This can prevent the first and second substrates from bending at the center.

In the MEMS device, the contact layer may surround the MEMS structure as viewed in the opposing direction.

According to this configuration, the contact layer surrounds the MEMS structure as viewed in the opposing direction. The contact layer thus has a large area as viewed in the opposing direction. Furthermore, the distances between the first joint portion and the contact layer at all locations can be substantially equal. Therefore, the control of the interval between the first and second substrates by the contact layer can be easily performed with high accuracy.

In the MEMS device, the distance between the first joint portion and the contact layer may be, for example, less than or equal to about 1 mm and greater than or equal to 0 mm as viewed in the opposing direction.

When the first joint portion is distant from the contact layer as viewed in the opposing direction, the load on the first joint portion, which is in liquid form and has a fluidity under high load in the manufacturing process of the MEMS device, could be excessively high in some localities. According to the aforementioned configuration, the distance between the first joint portion and the contact layer is, for example, less than or equal to about 1 mm as viewed in the opposing direction. This can reduce the application of local excessive load on the first joint portion as described above.

In the MEMS device, the area of the contact layer may be, for example, greater than or equal to about 8% of the area of the first joint portion and may be less than or equal to the area of the first substrate excluding a region overlapping the first joint portion as viewed in the opposing direction.

When the area of the contact layer is small as viewed in the opposing direction, excessively high load on the contact layers could deform the contact layer at high temperature under high load in the manufacturing process of the MEMS device. According to the aforementioned configuration, the area of the contact layer as viewed in the opposing direction is greater than or equal to about 8% of the area of the first joint portion. Therefore, in the manufacturing process of the MEMS device, the load on the contact layer is less likely to excessively increase at high temperature under high load.

A method of manufacturing a MEMS device according to an aspect of the present invention includes a first metal layer formation step of forming on a major surface of a first substrate including a MEMS structure, a first metal layer that includes a first type of metal and surrounds the MEMS structure, a second metal layer formation step of forming in a region corresponding to the first metal layer on a major surface of a second substrate, a second metal layer including a second type of metal that is able to undergo a metal eutectic reaction with the first type of metal, a contact layer formation step of forming on the major surface of the first substrate or the major surface of the second substrate, a contact layer including one of the first type of metal and the second type of metal, and a joint step of, after executing the first metal layer formation step, the second metal layer formation step, and the contact layer formation step, arranging the major surface of the first substrate and the major surface of the second substrate opposite to each other in the opposing direction and bringing the first substrate and the second substrate close to each other until the contact layer comes into contact with the major surface of the first substrate and the major surface of the second substrate to cause the first metal layer and the second metal layer to undergo a metal eutectic reaction.

According to this manufacturing method, the interval between the first and second substrates can be controlled to be equal or substantially equal to the total height of the contact layer by the contact layer coming into contact with the major surface of the first substrate and the major surface of the second substrate in the joint step.

The temperature at which the plurality of types of metal undergo a metal eutectic reaction is lower than the melting point of each of the plurality of types of metal. The first type of metal included in the first metal layer and the second type of metal included in the second metal layer undergo a metal eutectic reaction at a temperature lower than the melting points of the first and second types of metal. According to this manufacturing method, the contact layer includes one of the first type of metal and the second type of metal. In the joint step, the melting point of the metal included in the contact layer is therefore higher than the temperature at which the metal eutectic reaction occurs. This means that the contact layer can be chemically stabilized in a high-temperature and high-load condition where the metals undergo a metal eutectic reaction. It is therefore possible to reduce deformation of the contact layer in the joint step, thus making variations in interval between the first and second substrates smaller.

According to the aforementioned manufacturing method, the contact layer includes one of the first type of metal and the second type of metal. In the case where the contact layer includes the first type of metal, even if the metal included in the contact layer is mixed into the first metal layer in the joint step, its influence on the first metal layer can be made smaller. In the case where the contact layer includes the second type of metal, even if the metal included in the contact layer is mixed into the second metal layer in the joint step, its influence on the second metal layer can be made smaller.

In the method of manufacturing a MEMS device, the total length of the first metal layer and the second metal layer in the opposing direction may be greater than the length of the contact layer in the opposing direction.

According to this manufacturing method, the total length of the first and second metal layers in the opposing direction is greater than the total length of the contact layer in the opposing direction. This allows for application of high load to the first metal layer and the second metal layer in the joint step.

In the method of manufacturing a MEMS device, in the first metal layer formation step, a third metal layer including the first type of metal may be defined inside the first metal layer on the major surface of the first substrate, in the second metal layer formation step, a fourth metal layer including the second type of metal may be defined in a region corresponding to the third metal layer on the major surface of the second substrate, and in the joint step, the third metal layer and the fourth metal layer may undergo a metal eutectic reaction.

According to this manufacturing method, the third metal layer is defined inside the first metal layer as viewed in the opposing direction. Therefore, the third metal layer can be formed closer to the MEMS structure than that in the manufacturing method in which the third metal layer is formed outside the first metal layer as viewed in the opposing direction. The third metal layer and the MEMS structure can therefore be electrically coupled with short wiring.

In the method of manufacturing a MEMS device, at least one of the third metal layer and the fourth metal layer may include at least a portion of materials defining the first substrate or the second substrate that is adjacent to the at least one of the third metal layer and the fourth metal layer.

According to this manufacturing method, the third and fourth metal layers include at least a portion of the same materials as those defining the first and second substrates. In the process of the metal eutectic reaction between the first type of metal and the second type of metal in the joint step, the materials included in the third and fourth metal layers diffuse into the first substrate and the second substrate. This allows the third and fourth metal layers to maintain ohmic contact with the first and second substrates.

The method of manufacturing a MEMS device according to an example embodiment of the present invention may further include an insulating layer formation step of forming an insulating layer electrically insulated, on at least one of the major surface of the first substrate and the major surface of the second substrate. In the method of manufacturing a MEMS device, in the contact layer formation step, the contact layer may be formed on the insulating layer formed on at least one of the major surface of the first substrate and the major surface of the second substrate or in a region corresponding to the insulating layer on the major surface of the first substrate or the major surface of the second substrate.

An unintended electrical coupling between the first and second substrates through the contact layer creates unwanted wiring in the MEMS device. In this case, a stray capacitance could be produced, for example, between the unwanted wiring and a via conductor or an electrode pad defined in the second substrate. The stray capacitance could deteriorate the electric characteristics of the MEMS device. Furthermore, the unwanted wiring could increase the power consumption of the MEMS device.

According to this manufacturing method, the insulating layer prevents electrical coupling between the first and second substrates through the contact layer. It is therefore possible to prevent the formation of stray capacitance or increase in power consumption described above.

In the method of manufacturing a MEMS device, the insulating layer defined in the insulating layer formation step may include a first insulating layer overlapping the first metal layer and the second metal layer as viewed in the opposing direction when the major surface of the first substrate and the major surface of the second substrate are arranged opposite to each other in the opposing direction in the joint step, and a second insulating layer overlapping the contact layer as viewed in the opposing direction when the major surface of the first substrate and the major surface of the second substrate are arranged opposite to each other in the opposing direction in the joint step. When the insulating layer is formed on the major surface of the first substrate, the first metal layer may be formed on the major surface of the first substrate with the first insulating layer interposed therebetween in the first metal layer formation step. When the insulating layer is formed on the major surface of the second substrate, the second metal layer may be formed on the major surface of the second substrate with the first insulating layer interposed therebetween in the second metal layer formation step. In the contact layer formation step, the contact layer may be formed on the second insulating layer formed on at least one of the major surface of the first substrate and the major surface of the second substrate or in a region corresponding to the second insulating layer on the major surface of the first substrate or the major surface of the second substrate.

According to this manufacturing method, insulating layers are formed both at the position corresponding to the first and second metal layers and at the position corresponding to the contact layer. This can make the height difference between these positions smaller. Therefore, the control of the interval between the first and second substrates by the formation of the contact layer can be easily performed with high accuracy.

The method of manufacturing a MEMS device according to an example embodiment of the present invention may further include a recess formation step of forming a recess in the major surface of the first substrate or the major surface of the second substrate. In the method of manufacturing a MEMS device, in the insulating layer formation step, the insulating layer may be formed by filling the recess.

According to this manufacturing method, the insulating layers can be formed so as not to protrude from the major surface of the first substrate and the major surface of the second substrate. For example, the insulating layers can be provided so as to be flush with the major surface of the first substrate and the major surface of the second substrate. Therefore, the control of the interval between the first and second substrates by the formation of the contact layer can be easily performed with high accuracy.

### First Example Embodiment

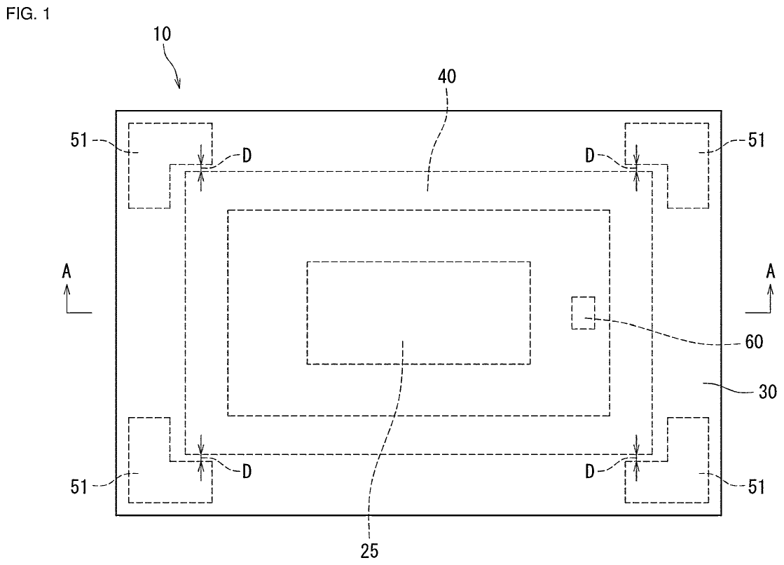

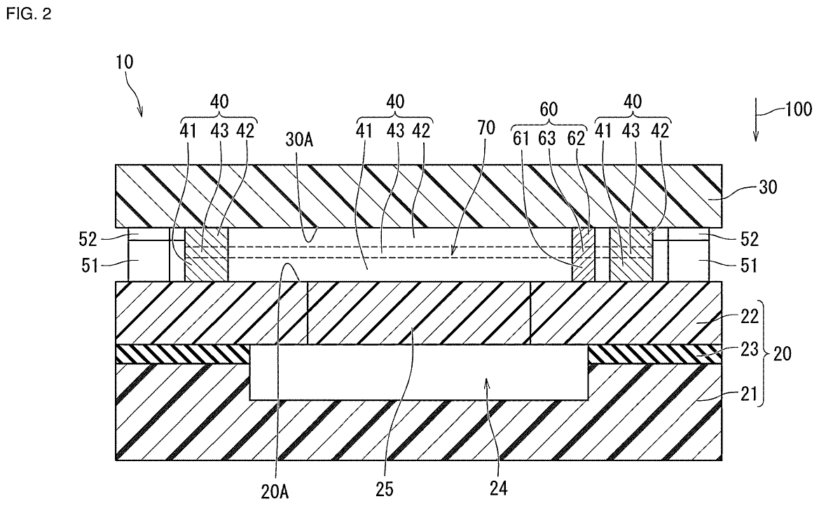

FIG. 1 is a plan view of a MEMS device according to a first example embodiment of the present invention. FIG. 2 is a cross-sectional view of an A-A cross section of FIG. 1. The MEMS device according to the first example embodiment and MEMS devices according to later-described example embodiments are preferably applied to, for example, acceleration sensors, angular rate sensors, radio-frequency filters, MEMS switches, or the like.

As illustrated in FIGS. 1 and 2, in the first example embodiment, the shape of a MEMS device 10 is preferably a cuboid shape. The MEMS device 10 includes a first substrate 20, a second substrate 30, a first joint portion 40, contact layers 51, insulating layers 52, and a second joint portion 60. The insulating layers 52 are an example of a first insulating layer. The shape of the MEMS device 10 may be other than a cuboid.

In the following description, the direction in which the first substrate 20 and the second substrate 30 are provided on each other with the first joint portion 40, the contact layers 51, and the insulating layers 52 interposed therebetween is referred to as an opposing direction 100. In the following description, for convenience of explanation, the side of the MEMS device 10 in which the second substrate 30 is provided is referred to as an upper side, and the side in which the first substrate 20 is provided is referred to as a lower side.

As illustrated in FIG. 2, in the MEMS device 10, the second substrate 30 is provided on top of the first substrate 20 with the first joint portion 40, the contact layers 51, and the insulating layers 52 interposed therebetween.

The first substrate 20 includes a lower layer 21, an upper layer 22, and an insulating layer 23. The main material of each of the lower layer 21 and the upper layer 22 is, for example, preferably silicon (Si). That is, the lower layer 21 and the upper layer 22 include, for example, silicon. The term “main material” refers to a material whose proportion is the largest among the materials included in a particular portion (the lower layer 21, for example). The insulating layer 23 is made of an insulator that is electrically insulated. For example, the insulating layer 23 is made of silicon dioxide (SiO₂) in the first example embodiment. The insulating layer 23 is sandwiched between the lower layer 21 and the upper layer 22 and is joined to the lower layer 21 and the upper layer 22. That is, the lower layer 21 and the upper layer 22 are joined with the insulating layer 23 interposed therebetween. In the first example embodiment, therefore, the first substrate 20 is an SOI (silicon-on-insulator) substrate. The first substrate 20 is not limited to an SOI substrate. For example, the lower layer 21 and the upper layer 22 may include a piezoelectric monocrystal material (LT, LN, or the like), such as LN (LiNbO₃) or a LT (LiTaO₃) instead of silicon. For example, the insulating layer 23 may be made of an insulator (SiO₂, for example) other than silicon dioxide.

A recess is provided in the lower layer 21 and the insulating layer 23. The upper portion of the recess is covered with the upper layer 22. An air gap 24 is thus provided in the first substrate 20.

The upper layer 22 includes a MEMS structure 25. The upper layer 22 and the MEMS structure 25 are integrally provided. In the first example embodiment, the MEMS structure 25 is a structure including a fixed portion fixed to the upper layer 22 of the first substrate 20 and a moving portion that is coupled to the fixed portion and resonates relative to the fixed portion. The moving portion is a resonator (a MEMS resonator manufactured using a MEMS technology). The MEMS structure 25 opposes the air gap 24 and a later-described air gap 70. In other words, the MEMS structure 25 is at the position overlapping the spaces 24 and 70 as viewed in the opposing direction 100. Between the fixed portion and the moving portion, a not-illustrated gap is provided. The MEMS structure 25 (to be specific, the moving portion of the MEMS structure 25) is able to vibrate in a space including the air gaps 24 and 70 and the gap. The air gaps 24 and 70 communicate with each other (not illustrated). The air gaps 24 and 70 define a closed space while communicating with each other.

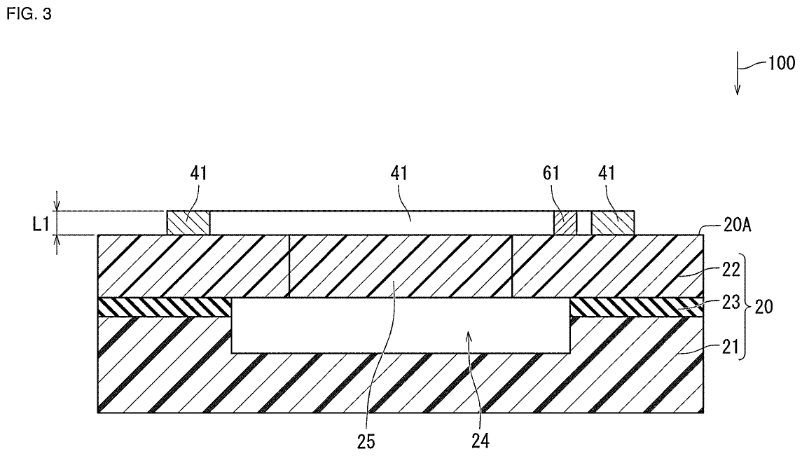

In addition to silicon, the MEMS structure 25 includes a piezoelectric thin film or a metal layer, which is not illustrated in FIG. 2 and FIGS. 3, 4, 7, 8, and 13 described later. The piezoelectric thin film and the metal layer may be provided only inside the MEMS structure 25 or may be provided both inside and outside the MEMS structure 25 (a portion of the upper layer 22 other than the MEMS structure 25).

The resonator can be of various types of resonators that are publicly known (for example, a resonator using an out-of-plane bending vibration mode, a resonator using a thickness expansion mode, and a resonator using a Lamb wave vibration mode). The MEMS structure 25 is not limited to the resonator and may be, for example, an acceleration sensor or a strain sensor statically driven.

The second substrate 30 is located opposite to the first substrate 20 in the opposing direction 100 above the first substrate 20. The second substrate 30 is spaced from the first substrate 20 in the opposing direction 100. The main material of the second substrate 30 is silicon. That is, the second substrate 30 includes, for example, silicon. The main material of the second substrate 30 may be other than silicon, for example, glass.

In the first substrate 20 and the second substrate 30, a via conductor and an electrode pad, which are not illustrated in the drawings, can be provided. The via conductor is formed by, for example, filling a through-hole, a recess, or a closed space defined in a conductive substrate with an insulating material. The method of forming the via conductor is not limited to the above method. The via conductor may be formed by, for example, filling a through-hole, a recess, or a closed space defined in a substrate with a conductive paste. The electrode pad is formed by, for example, a semiconductor process. The method of forming the electrode pad is not limited to a semiconductor process and may be, for example, printing or the like.

The first joint portion 40 is provided between the first substrate 20 and the second substrate 30. The lower end portion of the first joint portion 40 is joined to a major surface 20A (the upper surface of the upper layer 22 of the first substrate 20) of the first substrate 20. The upper end portion of the first joint portion 40 is joined to a major surface 30A (the lower surface of the second substrate 30) of the second substrate 30.

As illustrated in FIG. 1, the first joint portion 40 is preferably ring-shaped as viewed in the opposing direction 100. The first joint portion 40 surrounds the MEMS structure 25 of the first substrate 20 as viewed in the opposing direction 100. The air gap 70 surrounded by the first substrate 20, the second substrate 30, and the first joint portion 40 is thus provided.

As illustrated in FIG. 2, the first joint portion 40 includes a first metal layer 41, a second metal layer 42, and a eutectic layer 43. However, the first metal layer 41 and the second metal layer 42 sometimes do not remain distinct as a result of a metal eutectic reaction across the entirety of the first joint portion 40 in the manufacturing process of the MEMS device 10. In such a case, the first joint portion 40 is made of only the eutectic layer 43.

The first metal layer 41 is joined to the major surface 20A of the first substrate 20. The second metal layer 42 is joined to the major surface 30A of the second substrate 30.

The main materials of the first metal layer 41 and the second metal layer 42 are, for example, preferably aluminum (Al), gold (Au), indium (In), tin (Sn), germanium (Ge), or the like, provided that the main material of the first metal layer 41 and the main material of the second metal layer 42 are able to undergo a metal eutectic reaction. In the first example embodiment, the main material of the first metal layer 41 is, for example, aluminum while the main material of the second metal layer 42 is, for example, germanium. In the first example embodiment, the first metal layer 41 and the second metal layer 42 include, for example, small amounts of copper (Cu) and titanium (Ti).

The eutectic layer 43 is positioned between the first metal layer 41 and the second metal layer 42. The eutectic layer 43 is undergoing a metal eutectic reaction with the first metal layer 41 and the second metal layer 42. The main material of the eutectic layer 43 is a eutectic alloy of metal included in the first metal layer 41 and metal included in the second metal layer 42. In the first example embodiment, the main material of the eutectic layer 43 is, for example, a eutectic alloy of aluminum as the main material of the first metal layer 41 and germanium as the main material of the second metal layer 42. That is, in the first example embodiment, for example, aluminum and germanium correspond to a plurality of types of metal.

The contact layers 51 are arranged between the first substrate 20 and the second substrate 30. The lower end portions of the contact layers 51 are in contact with the major surface 20A of the first substrate 20. The upper end portions of the contact layers 51 are provided on the respective insulating layers 52.

As illustrated in FIG. 1, the contact layers 51 are positioned outside the first joint portion 40 as viewed in the opposing direction 100. In the first example embodiment, the MEMS device 10 includes four contact layers 51. The four contact layers 51 are positioned adjacent the respective four vertices of the first joint portion 40 having a rectangular shape as viewed in the opposing direction 100.

As illustrated in FIG. 2, the insulating layers 52 are provided on the contact layers 51. In the first example embodiment, the insulating layers 52 are positioned above the contact layers 51. The lower end portions of the contact layers 51 are in contact with the major surface 20A of the first substrate 20. The upper end portions of the insulating layers 52 are in contact with the major surface 30A of the second substrate 30. The contact layers 51 are therefore in contact with the second substrate 30 with the insulating layers 52 interposed therebetween. That is, in FIG. 2, the contact layers 51 are directly in contact with the first substrate 20 and are indirectly in contact with the second substrate 30. The “being indirectly in contact with” refers to that the contact layers 51 are in contact with the first substrate 20 (the second substrate 30 in another example described later) with the insulating layers 52 interposed therebetween.

The contact layers 51 include a portion of the same plural types of metal as those defining the eutectic alloy as the main material of the eutectic layer 43 of the first joint portion 40. In the first example embodiment, the contact layers 51 include a portion of the same two metals (aluminum and germanium) as those defining the eutectic alloy of the eutectic layer 43. That is, the contact layers 51 include either aluminum or germanium. The contact layers 51 do not include a eutectic alloy. When the portion of the plural types of metal include plural types of metal, the portion of the plural types of metal are composed of plural types of metal that are not able to undergo a eutectic reaction with each other.

The contact layers 51 may include only a portion (for example, only one of aluminum and germanium in the first example embodiment) of the same plural types of metal as those defining the eutectic alloy of the eutectic layer 43 or may include a material other than the plural types of metal, for example, tin.

In the first example embodiment, the contact layers 51 includes as the main material, a portion of the same plural types of metal (for example, aluminum and germanium) as those defining the eutectic alloy of the eutectic layer 43. However, the contact layers 51 may include a material other than the plural types of metal as the main material provided that the contact layers 51 include a portion of the same plural types of metal as those defining the eutectic alloy of the eutectic layer 43. For example, when the first metal layer 41 includes gold, the second metal layer 42 includes indium, and the eutectic layer 43 includes a eutectic alloy of gold and indium, the contact layers 51 may include gold or indium as the main material.

The insulating layers 52 are made of an insulator that is electrically insulated. For example, in the first example embodiment, the insulating layers 52 are made of silicon dioxide (SiO₂). The insulating layers 52 are interposed between the respective contact layers 51 and the second substrate 30. The contact layers 51 and the first substrate 20 are electrically insulated from the second substrate 30.

As described above, the insulating layers 52 are positioned above the contact layers 51. The insulating layers 52 may be positioned below the contact layers 51. In this case, the lower end portions of the insulating layers 52 are in contact with the major surface 20A of the first substrate 20. That is, the contact layers 51 are in contact with the first substrate 20 with the insulating layers 52 interposed therebetween. The upper end portions of the contact layers 51 are in contact with the major surface 30A of the second substrate 30. In this case, the contact layers 51 are indirectly in contact with the first substrate 20 and are directly in contact with the second substrate 30.

In addition, the insulating layers 52 may be positioned both above and below the contact layers 51. In other words, two insulating layers 52 may sandwich each contact layer 51 in the opposing direction 100. In this case, the lower end portion of one of the two insulating layers 52 is in contact with the major surface 20A of the first substrate 20. That is, the contact layer 51 is in contact with the first substrate 20 with the one insulating layer 52 interposed therebetween. The upper end portion of the other insulating layer 52 is in contact with the major surface 30A of the second substrate 30. That is, the contact layer 51 is in contact with the second substrate 30 with the other insulating layer 52 interposed therebetween. That is, in this case, the contact layer 51 is indirectly in contact with the first substrate 20 and is indirectly in contact with the second substrate 30.

Each insulating layer 52 may be positioned between two contact layers 51 in the opposing direction 100. In other words, each insulating layer 52 may be sandwiched by two contact layers 51 in the opposing direction 100. In this case, the lower end portion of one of the two contact layers 51 is in contact with the major surface 20A of the first substrate 20. The upper end portion of the other contact layer 51 is in contact with the major surface 30A of the second substrate 30. That is, in this case, one of the two contact layers 51 is directly in contact with the first substrate 20 while the other contact layer 51 is directly in contact with the second substrate 30.

The length of each contact layer 51 and each insulating layer 52 in the opposing direction 100 is preferably equal to or substantially equal to the length of the first joint portion 40 in the opposing direction 100. The length of the first joint portion 40 in the opposing direction 100 may be greater than the total length of each contact layer 51 and each insulating layer 52 in the opposing direction 100. For example, when the interval between the first substrate 20 and the second substrate 30 varies due to warpage of at least one of the first substrate 20 and the second substrate 30, the length of the first joint portion 40 in the opposing direction 100 can be greater than the total length of each contact layer 51 and each insulating layer 52 in the opposing direction 100. For example, when at least one of the upper and lower end portions of the first joint portion 40 is embedded in the first substrate 20 or the second substrate 30, the length of the first joint portion 40 in the opposing direction 100 can be greater than the total length of each contact layer 51 and each insulating layer 52 in the opposing direction 100.

As illustrated in FIG. 2, the second joint portion 60 is located between the first substrate 20 and the second substrate 30. The lower end portion of the second joint portion 60 is joined to the major surface 20A of the first substrate 20. The upper end portion of the second joint portion 60 is joined to the major surface 30A of the second substrate 30.

As illustrated in FIG. 1, the second joint portion 60 is positioned inside the first joint portion 40 as viewed in the opposing direction 100. The second joint portion 60 is positioned between the first joint portion 40 and the MEMS structure 25 in the first substrate 20 as viewed in the opposing direction 100.

As illustrated in FIG. 2, the second joint portion 60 includes a third metal layer 61, a fourth metal layer 62, and a eutectic layer 63.

The third metal layer 61 is joined to the major surface 20A of the first substrate 20. The fourth metal layer 62 is joined to the major surface 30A of the second substrate 30.

The main materials of the third metal layer 61 and the fourth metal layer 62 are preferably, for example, aluminum (Al), gold (Au), indium (In), tin (Sn), germanium (Ge), or the like, provided that the main material of the third metal layer 61 and the main material of the fourth metal layer 62 are able to undergo a metal eutectic reaction. In the first example embodiment, the main material of the third metal layer 61 is the same as the main material of the first metal layer 41, and the main material of the fourth metal layer 62 is the same as the main material of the second metal layer 42. Specifically, for example, the main material of the third metal layer 61 is aluminum, and the main material of the fourth metal layer 62 is germanium. In the first example embodiment, for example, the third metal layer 61 and the fourth metal layer 62 include small amounts of copper (Cu) and titanium (Ti). The main material of the third metal layer 61 may be different from the main material of the first metal layer 41 if so desired. The main material of the fourth metal layer 62 may be different from the main material of the second metal layer 42 if so desired.

The second joint portion 60 includes at least a portion of the same materials as those defining the first substrate 20 and the second substrate 30. In the first example embodiment, for example, the third metal layer 61 includes silicon, which is the material defining the upper layer 22 of the first substrate 20, and the fourth metal layer 62 includes silicon, which is the material defining the second substrate 30.

When the first substrate 20 includes a first material and the second substrate 30 includes a second material that is different from the first material, the third metal layer 61 may include the first material while the fourth metal layer 62 includes the second material. Furthermore, only one of the third metal layer 61 and the fourth metal layer 62 may include at least one of the first material and the second material, regardless of whether the first and second materials are the same.

The eutectic layer 63 is positioned between the third metal layer 61 and the fourth metal layer 62. The eutectic layer 63 is undergoing a metal eutectic reaction individually with the third metal layer 61 and the fourth metal layer 62. The eutectic layer 63 includes as the main material, the eutectic alloy of metal included in the third metal layer 61 and metal included in the fourth metal layer 62. In the first example embodiment, for example, the eutectic layer 63 includes as the main material, a eutectic alloy of aluminum, which is the main material of the third metal layer 61, and germanium, which is the main material of the fourth metal layer 62.

As illustrated in FIG. 1, a distance D between the first joint portion 40 and each contact layer 51 is, for example, preferably less than or equal to about 1 mm in the first example embodiment. The distance D is the shortest distance between the first joint portion 40 and each contact layer 51. The first joint portion 40 and each contact layer 51 may be in contact with each other. That is, the distance D is, for example, less than or equal to about 1 mm and greater than or equal to 0 mm. The distance D may be greater than about 1 mm if so desired. In the first example embodiment, lengths (the vertical and horizontal lengths in FIG. 1) of the MEMS device 10 in in-plane directions are about 0.8 mm to about 5 mm, for example, and the thickness (the length in the opposing direction 100 in FIG. 2) of the MEMS device 10 is about 0.5 mm to about 1 mm, for example.

As illustrated in FIG. 1, the area of the contact layers 51 is, for example, greater than or equal to about 8% of the area of the first joint portion 40 as viewed in the opposing direction 100. The contact layers 51 may cover the entire or substantially the entire region excluding the region overlapping the first joint portion 40 as viewed in the opposing direction 100. That is, the area of the contact layers 51 is less than or equal to the area of the first substrate 20 excluding the region overlapping the first joint portion 40 as viewed in the opposing direction 100.

According to the first example embodiment, the first substrate 20, the second substrate 30, and the first joint portion 40 define a space for the MEMS structure 25 to vibrate.

According to the first example embodiment, the contact layers 51 and the insulating layers 52 come into contact with the first substrate 20 and the second substrate 30 in the manufacturing process of the MEMS device 10, so that the interval between the first substrate 20 and the second substrate 30 can be controlled so as to be equal or substantially equal to the height of each contact layer 51 and each insulating layer 52.

The temperature at which plural types of metal undergo a metal eutectic reaction is lower than the melting point of each of the plural types of metal. The plural types of metal included in the first joint portion 40 undergo a metal eutectic reaction at a temperature lower than the melting point of each of the plural types of metal in the manufacturing process of the MEMS device 10. Herein, according to the first example embodiment, the contact layers 51 include a portion of the same plural types of metal as the first joint portion 40. The melting point of the metal included in the contact layers 51 is therefore higher than the temperature at which the plural types of metal included in the first joint portion 40 undergo a metal eutectic reaction in the manufacturing process of the MEMS device 10. This means that the contact layers 51 can be chemically stabilized in a high-temperature and high-load condition where the metals undergo a metal eutectic reaction. It is therefore possible to reduce deformation of the contact layers 51 in the manufacturing process of the MEMS device 10, thus making variations in interval between the first substrate 20 and the second substrate 30 smaller.

According to the first example embodiment, the contact layers 51 include a portion of the same plural types of metal as the first joint portion 40. Therefore, even if the metal included in the contact layers 51 is mixed into the first joint portion 40 in the manufacturing process of the MEMS device 10, its influence on the first joint portion 40 can be made smaller.

According to the first example embodiment, the length of the first joint portion 40 in the opposing direction 100 is greater than or equal to the length of the contact layers 51 in the opposing direction 100. This allows for application of high load to the first metal layer 41 and the second metal layer 42 of the first joint portion 40 in the manufacturing process of the MEMS device 10.

According to the first example embodiment, the second joint portion 60 is positioned inside the first joint portion 40 as viewed in the opposing direction 100. The second joint portion 60 is therefore closer to the MEMS structure 25 than that in a configuration where the second joint portion 60 is positioned outside the first joint portion 40 as viewed in the opposing direction 100. The second joint portion 60 and the MEMS structure 25 can therefore be electrically coupled with short wiring.

According to the first example embodiment, the second joint portion 60 includes at least a portion of the same materials as those defining the first substrate 20 and the second substrate 30. In the manufacturing process of the MEMS device 10, when the plural types of metal undergo a metal eutectic reaction to form a eutectic alloy, the materials included in the second joint portion 60 diffuse into the first substrate 20 and the second substrate 30. This allows the second joint portion 60 to maintain ohmic contact with at least one of the first substrate 20 and the second substrate 30. Therefore, when the second joint portion 60 is used as wiring, the second joint portion 60 and at least one of the first substrate 20 and the second substrate 30 can be electrically coupled with a high degree of reliability.

An unintended electrical coupling between the first substrate 20 and the second substrate 30 through the contact layer 51 creates unwanted wiring in the MEMS device 10. In this case, a stray capacitance could be generated, for example, between the unwanted wiring and a via conductor or an electrode pad defined in the second substrate 30. The stray capacitance could deteriorate the electric characteristics of the MEMS device 10. Furthermore, the unwanted wiring could increase the power consumption of the MEMS device 10.

According to the first example embodiment, the insulating layers 52 prevent the first substrate 20 and the second substrate 30 from being electrically coupled to each other through the contact layers 51. It is therefore possible to prevent the generation of stray capacitance and increase in power consumption described above.

When the first joint portion 40 is distant from the contact layers 51 as viewed in the opposing direction 100, the load on the first joint portion 40, which is in liquid form and has a fluidity under high load in the manufacturing process of the MEMS device 10, could be excessively high in some localities. According to the first example embodiment, the distance between the first joint portion 40 and the contact layers 51 as viewed in the opposing direction 100 is, for example, less than or equal to about 1 mm. This can reduce the application of local excessive load to the first joint portion 40 described above.

When the total area of the contact layers 51 is small as viewed in the opposing direction 100, excessively high load on the contact layers 51 at high temperature under high load in the manufacturing process of the MEMS device 10 could deform the contact layers 51. According to the first example embodiment, the total area of the contact layers 51 as viewed in the opposing direction 100 is greater than or equal to about 8% of the area of the first joint portion 40. Therefore, in the manufacturing process of the MEMS device 10, the load on the contact layers 51 is less likely to excessively increase at high temperature under high load.

The MEMS device 10 includes the insulating layers 52 in the first example embodiment but does not need to include the insulating layers 52. In this case, the lower end portions of the contact layers 51 are in contact with the major surface 20A of the first substrate 20. The upper end portions of the contact layers 51 are in contact with the major surface 30A of the second substrate 30. That is, in this case, the contact layers 51 are directly in contact with the first substrate 20 and are directly in contact with the second substrate 30.

### Manufacturing Method of MEMS Device According to First Example Embodiment

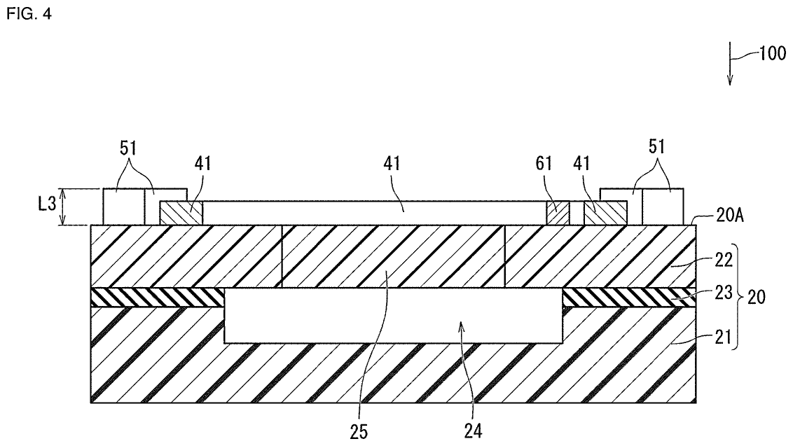

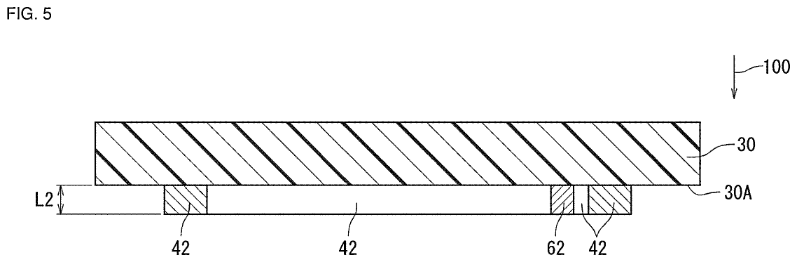

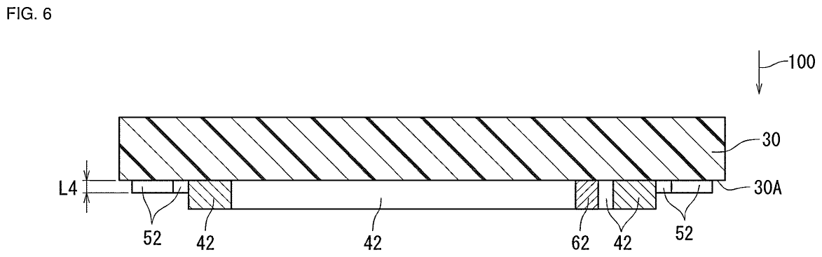

Hereinafter, an example of a manufacturing method of the MEMS device 10 according to the first example embodiment will be described with reference to FIGS. 3 to 6. FIG. 3 is a cross-sectional view when first and third metal layers are provided on the first substrate in the manufacturing process of the MEMS device according to the first example embodiment of the present invention. FIG. 4 is a cross-sectional view when contact layers are provided on the first substrate in the manufacturing process of the MEMS device according to the first example embodiment of the present invention. FIG. 5 is a cross-sectional view when second and fourth metal layers are provided on the second substrate in the manufacturing process of the MEMS device according to the first example embodiment of the present invention. FIG. 6 is a cross-sectional view when insulating layers are provided on the second substrate in the manufacturing process of the MEMS device according to the first example embodiment of the present invention.

The MEMS device 10 is manufactured by singulation of a multilayer body into plural pieces. The multilayer body integrally includes a plurality of MEMS devices 10 that are arrayed. FIGS. 3 to 6 illustrate only a portion of the multilayer body corresponding to one MEMS device 10 for convenience of explanation. The manufacturing method of the MEMS device 10 according to the first example embodiment includes: a first metal layer formation step, a contact layer formation step, a second metal layer formation step, an insulating layer formation step, a joint step, a grinding step, an electrode formation step, and a singulation step.

### First Metal Layer Formation Step

First, the first metal layer formation step is executed. In the first metal layer formation step, the first substrate 20 is prepared as illustrated in FIG. 3. The first substrate 20 is preferably manufactured by, for example, a publicly-known method. As described above, the first substrate 20 includes the lower layer 21, the upper layer 22, which is disposed opposite to the lower layer 21 and includes the MEMS structure 25, and the insulating layer 23, which is interposed between the lower layer 21 and the upper layer 22. In the first substrate 20, the air gap 24 is formed. The MEMS structure 25 faces the air gap 24. In the first substrate 20, a via conductor (a through-silicon via (TSV), for example) or an electrode pad, not illustrated, may be previously formed.

On the major surface 20A of the first substrate 20, the first metal layer 41 and the third metal layer 61 are formed. As described above, in the first example embodiment, the main materials of the first metal layer 41 and the third metal layer 61 are aluminum. Aluminum is an example of a first type of metal. The first type of metal is able to undergo a metal eutectic reaction with a later-described second type of metal. The first type of metal may be other than aluminum, provided with the first type of metal is able to undergo a metal eutectic reaction with the second type of metal. For example, the first type of metal may be gold, indium, tin, germanium, or the like.

The third metal layer 61 includes silicon, which is the material defining the upper layer 22 of the first substrate 20 adjacent to the third metal layer 61.

The third metal layer 61 is formed at a position different from the MEMS structure 25. The first metal layer 41 is ring-shaped as viewed in the opposing direction 100. The first metal layer 41 is provided so as to surround the MEMS structure 25 and the third metal layer 61 as viewed in the opposing direction 100. That is, the third metal layer 61 is defined inside the first metal layer 41 on the major surface 20A.

The first metal layer 41 and the third metal layer 61 are formed by, for example, a semiconductor process. The method of forming the first metal layer 41 and the third metal layer 61 is not limited to a semiconductor process and may be, for example, printing or the like.

### Contact Layer Formation Step

Next, the contact layer formation step is executed. In the contact layer formation step, the contact layers 51 are provided on the major surface 20A of the first substrate 20 as illustrated in FIG. 4. The contact layers 51 include one of the first type of metal (for example, aluminum in this manufacturing method) and the later-described second type of metal (for example, germanium in this manufacturing method).

In this manufacturing method, four contact layers 51 are formed outside the first metal layer 41 as viewed in the opposing direction 100. The four contact layers 51 are formed adjacent the respective four vertices of the first metal layer 41 having a rectangular shape as viewed in the opposing direction 100.

The contact layers 51 are preferably formed by, for example, a semiconductor process. The method of forming the contact layers 51 is not limited to a semiconductor process and may be, for example, printing or the like.

### Second Metal Layer Formation Step

Next, the second metal layer formation step is executed. In the second metal layer formation step, the second substrate 30 is prepared as illustrated in FIG. 5. The second substrate 30 is preferably manufactured by, for example, a publicly-known method. In the second substrate 30, a via conductor (a through-silicon via (TSV), for example) or an electrode pad, not illustrated, may be included.

On the major surface 30A of the second substrate 30, the second metal layer 42 and the fourth metal layer 62 are formed. As described above, in the first example embodiment, the main materials of the second metal layer 42 and the fourth metal layer 62 are preferably germanium. Germanium is an example of the second type of metal. The second type of metal is able to undergo a metal eutectic reaction with the first type of metal. The second type of metal may be other than germanium, provided that the second type of metal is able to undergo a metal eutectic reaction with the first type of metal. For example, the second type of metal may be aluminum, gold, indium, tin, or the like.

The fourth metal layer 62 includes silicon, which is the material defining the second substrate 30 adjacent to the fourth metal layer 62.

The second metal layer 42 is formed in a region that corresponds to the first metal layer 41 when the second substrate 30 is disposed opposite to the first substrate 20 in the joint step described later. That is, the second metal layer 42 has the same size and the same shape (or substantially the same size and substantially the same shape) as the first metal layer 41 as viewed in the opposing direction 100.

The fourth metal layer 62 is formed in a region that corresponds to the third metal layer 61 when the second substrate 30 is disposed opposite to the first substrate 20 in the joint step described later. That is, the fourth metal layer 62 has the same size and the same shape (or substantially the same size and substantially the same shape) as the third metal layer 61 as viewed in the opposing direction 100.

The second metal layer 42 and the fourth metal layer 62 are preferably formed by, for example, a semiconductor process. The method of forming the second metal layer 42 and the fourth metal layer 62 is not limited to a semiconductor process and may be, for example, printing or the like.

### Insulating Layer Formation Step

Next, the insulating layer formation step is executed. In the insulating layer formation step, the insulating layers 52 are formed on the major surface 30A of the second substrate 30 as illustrated in FIG. 6. The insulating layers 52 are preferably made of an insulator (for example, silicon dioxide in the first example embodiment) electrically insulated.

The insulating layers 52 are formed in regions that correspond to the contact layers 51 when the second substrate 30 is provided opposite to the first substrate 20 in the later-described joint step. That is, the insulating layers 52 have the same sizes and the same shapes (or substantially the same sizes and substantially the same shapes) as the respective contact layers 51 as viewed in the opposing direction 100.

The insulating layers 52 are preferably formed by, for example, a semiconductor process.

The sum of length L4 (see FIG. 6) of each insulating layer 52 in the opposing direction 100 and length L3 (see FIG. 4) of each contact layer 51 in the opposing direction 100 is shorter than the sum of length L1 (see FIG. 3) and length L2 (see FIG. 5). The length L1 illustrated in FIG. 3 is the length of the first metal layer 41 in the opposing direction 100. The length L2 illustrated in FIG. 5 is the length L2 (see FIG. 5) of the second metal layer 42 in the opposing direction 100.

In this manufacturing method, the contact layers 51 are formed on the major surface 20A of the first substrate 20, and the insulating layers 52 are formed on the major surface 30A of the second substrate 30. However, the present invention is not limited to such a method.

For example, the insulating layers 52 may be provided on the major surface 20A of the first substrate 20 while the contact layers 51 are provided on the major surface 30A of the second substrate 30. In this case, the contact layers 51 are defined in regions that correspond to the respective insulating layers 52 when the second substrate 30 is disposed opposite to the first substrate 20 in the joint step.

Furthermore, for example, the contact layers 51 and the insulating layers 52 may be formed on the major surface 20A of the first substrate 20 together. In this case, the insulating layers 52 are formed on the major surface 20A of the first substrate 20 in the insulating layer formation step. Then the contact layer formation step is executed. In the contact layer formation step, the contact layers 51 are provided on the insulating layers 52. The contact layers 51 are thus formed on the major surface 20A of the first substrate 20 with the insulating layers 52 interposed therebetween.

Still furthermore, for example, the contact layers 51 and the insulating layers 52 may be formed on the major surface 30A of the second substrate 30 together. In this case, the insulating layers 52 are formed on the major surface 30A of the second substrate 30 in the insulating layer formation step. Then the contact layer formation step is executed. In the contact layer formation step, the contact layers 51 are provided on the insulating layers 52. The contact layers 51 are thus formed on the major surface 30A of the second substrate 30 with the insulating layers 52 interposed therebetween.

Still furthermore, for example, the insulating layers 52 may be formed on the major surface 20A of the first substrate 20 and the major surface 30A of the second substrate 30 in the insulating layer formation step. In this case, the contact layers 51 are provided on the insulating layers 52 formed on the major surface 20A or the insulating layers 52 formed on the major surface 30A in the contact layer formation step.

Thus, the contact layers 51 can be formed on the major surface 20A of the first substrate 20 or the major surface 30A of the second substrate 30.

The MEMS device 10 does not need to include the insulating layers 52. In this case, length L3 (see FIG. 4) of each contact layer 51 in the opposing direction 100 is shorter than the sum of length L1 (see FIG. 3) of the first metal layer 41 in the opposing direction 100 and length L2 (see FIG. 5) of the second metal layer 42 in the opposing direction 100.

Next, the joint step is executed. In the joint step, the first substrate 20 illustrated in FIG. 4 and the second substrate 30 illustrated in FIG. 6 are arranged opposite to each other in the opposing direction 100 so that the major surface 20A and the major surface 30A oppose each other. In this process, the first metal layer 41 and the second metal layer 42 are opposite to each other, the third metal layer 61 and the fourth metal layer 62 are opposite to each other, and the contact layers 51 and the insulating layers 52 are opposite to each other.

Next, loads of, for example, greater than or equal to about 10 MPa are preferably applied to the first substrate 20 and the second substrate 30 under a predetermined temperature. The direction of the load applied to the first substrate 20 is the direction toward the second substrate 30. The direction of the load applied to the second substrate 30 is a direction toward the first substrate 20.

The predetermined temperature is a temperature of, for example, higher than or equal to about 200° C. The predetermined temperature is set not lower than a temperature at which the main materials (for example, preferably aluminum in the first example embodiment) of the first metal layer 41 and the third metal layer 61 are able to undergo a metal eutectic reaction with the main materials (for example, preferably germanium in the first example embodiment) of the second metal layer 42 and the fourth metal layer 62, respectively. The predetermined temperature is set to a temperature lower than the melting points of the main materials (for example, preferably aluminum in the first example embodiment) of the first metal layer 41 and the third metal layer 61 and lower than the melting points of the main materials (for example, preferably germanium in the first example embodiment) of the second metal layer 42 and the fourth metal layer 62.

By the loads being applied to the first substrate 20 and the second substrate 30, the first substrate 20 and the second substrate 30 come close to each other, and the first metal layer 41 comes into contact with the second metal layer 42 while the third metal layer 61 comes into contact with the fourth metal layer 62. The contact layers 51 are not yet in contact with the insulating layers 52 at this time. This is because the sum of the lengths L1 and L2 is greater than the sum of the lengths L3 and L4.

Furthermore, in the situation where the first metal layer 41 and the third metal layer 61 are in contact with the second metal layer 42 and the fourth metal layer 62, respectively, when the contact layers 51 come close to the insulating layers 52, diffusion occurs.

That is, in the interface between the first metal layer 41 and the second metal layer 42, the main material (for example, preferably aluminum in the first example embodiment) of the first metal layer 41 and the main material (for example, preferably germanium in the first example embodiment) of the second metal layer 42 diffuse into each other to undergo a metal eutectic reaction. The eutectic layer 43, which includes as the main material the eutectic alloy of the main materials of the first metal layer 41 and the second metal layer 42, is thus formed between the first metal layer 41 and the second metal layer 42.

In the interface between the third metal layer 61 and the fourth metal layer 62, the main material (for example, preferably aluminum in the first example embodiment) of the third metal layer 61 and the main material (for example, preferably germanium in the first example embodiment) of the fourth metal layer 62 diffuse into each other to undergo a metal eutectic reaction. The eutectic layer 63, which includes as the main material the eutectic alloy of the main materials of the third metal layer 61 and the fourth metal layer 62, is thus formed between the third metal layer 61 and the fourth metal layer 62.

When the contact layers 51 come into contact with the insulating layers 52, in other words, when the contact layers 51 come into contact with the major surface 20A of the first substrate 20 and the major surface 30A of the second substrate 30 directly or with the insulating layers 52 interposed therebetween, the change in relative position of the first substrate 20 to the second substrate 30 due to the application of the loads stops. The positions of the first metal layer 41, the second metal layer 42, the third metal layer 61, and the fourth metal layer 62 are thus fixed, so that the aforementioned diffusion and metal eutectic reaction cannot occur anymore. Thus, as illustrated in FIG. 2, the first joint portion 40, which is composed of the first metal layer 41, the second metal layer 42, and the eutectic layer 43, is formed, and the second joint portion 60, which is composed of the third metal layer 61, the fourth metal layer 62, and the eutectic layer 63, is formed.

### Grinding Step

Next, the grinding step is executed. In the grinding step, the surface of the second substrate 30 opposite to the major surface 30A is ground and removed. When the second substrate 30 includes a through-silicon via, the through-silicon via can thus be exposed.

### Electrode Formation Step

Next, the electrode formation step is executed. In the electrode formation step, the through-silicon via exposed in the grinding step is preferably subjected to patterning of a metal thin film of, for example, gold, aluminum, or the like by a publicly-known process. An electrode pad is thus formed in the second substrate 30.

### Singulation Step

Next, the singulation step is executed. In the singulation step, the multilayer body is cut into plural MEMS devices 10. Cutting the multilayer body uses, for example, a dicing saw, a guillotine cutter, a laser, or the like.

According to this manufacturing method, the contact layers 51 come into contact with the major surface 20A of the first substrate 20 and the major surface 30A of the second substrate 30 directly or with the insulating layers 52 interposed therebetween in the joint step, so that the interval between the first substrate 20 and the second substrate 30 can be controlled so as to be equal to the total height of each contact layer 51 and each insulating layer 52.

The temperature at which plural types of metal undergo a metal eutectic reaction is lower than the melting point of each of the plural types of metal. The first type of metal included in the first metal layer 41 and the second type of metal included in the second metal layer 42 undergo a metal eutectic reaction at a temperature lower than the melting points of the first and second types of metal. According to this manufacturing method, the contact layers 51 include one of the first type of metal and the second type of metal. In the joint step, therefore, the melting point of the metal included in the contact layers 51 is higher than the temperature at which the metal eutectic reaction occurs. This means that the contact layers 51 can be chemically stabilized in a high-temperature and high-load condition where the metals undergo a metal eutectic reaction. It is therefore possible to reduce deformation of the contact layers 51 in the joint step, thus making variations in interval between the first substrate 20 and the second substrate 30 smaller.

According to this manufacturing method, the contact layers 51 include one of the first type of metal and the second type of metal. In the case where the contact layers 51 include the first type of metal, even if the metal included in the contact layers 51 is mixed into the first metal layer 41 in the joint step, its influence on the first metal layer 41 can be made smaller. In the case where the contact layers 51 include the second type of metal, even if the metal included in the contact layers 51 is mixed into the second metal layer 42 in the joint step, its influence on the second metal layer 42 can be made smaller.

According to this manufacturing method, the sum L1+L2 of the lengths of the first metal layer 41 and the second metal layer 42 in the opposing direction 100 is greater than the length L3 of the contact layers 51 in the opposing direction 100. This allows for application of high load to the first metal layer 41 and the second metal layer 42 in the joint step.

According to this manufacturing method, the third metal layer 61 is formed inside the first metal layer 41 as viewed in the opposing direction 100. Therefore, the third metal layer 61 can be formed closer to the MEMS structure 25 than that in the manufacturing method in which the third metal layer 61 is formed outside the first metal layer 41 as viewed in the opposing direction 100. The third metal layer 61 and the MEMS structure 25 can therefore be electrically coupled with short wiring.

According to this manufacturing method, the third metal layer 61 and the fourth metal layer 62 include at least a portion of the same materials as those defining the first substrate 20 and the second substrate 30. In the process of the metal eutectic reaction between the first type of metal and the second type of metal in the joint step, the materials included in the third metal layer 61 and the fourth metal layer 62 diffuse into the first substrate 20 and the second substrate 30. This allows the third metal layer 61 and the fourth metal layer 62 to maintain ohmic contact with the first substrate 20 and the second substrate 30.

An unintended electrical coupling between the first substrate 20 and the second substrate 30 through the contact layer 51 creates unwanted wiring in the MEMS device 10. In this case, a stray capacitance could be formed, for example, between the unwanted wiring and a via conductor or an electrode pad formed in the second substrate 30. The formed stray capacitance could deteriorate the electric characteristics of the MEMS device 10. In addition, the unwanted wiring could increase the power consumption of the MEMS device 10.

According to this manufacturing method, the insulating layers 52 prevent electrical coupling between the first substrate 20 and the second substrate 30 through the contact layers 51. It is therefore possible to prevent the formation of stray capacitance and increase in power consumption described above.

According to the aforementioned manufacturing method, the third metal layer 61 preferably includes, for example, silicon, which is the material defining the first substrate 20 adjacent to the third metal layer 61, and the fourth metal layer 62 preferably includes, for example, silicon, which is the material defining the second substrate 30 adjacent to the fourth metal layer 62. However, only one of the third metal layer 61 and the fourth metal layer 62 may include the same material (for example, silicon in the first example embodiment) as that defining the substrate adjacent thereto.

The order of the steps of the aforementioned manufacturing method is not limited to the aforementioned order. For example, the second metal layer formation step and the insulating layer formation step may be executed before the first metal layer formation step and the contact layer formation step.

### Second Example Embodiment

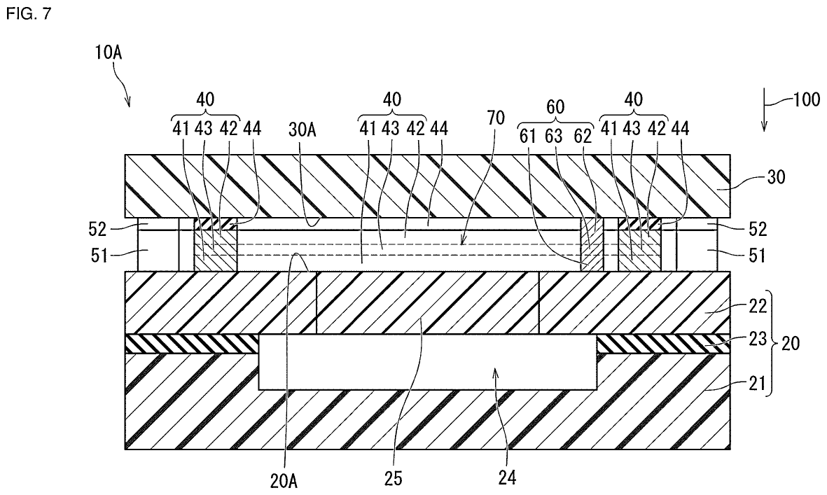

FIG. 7 is a cross-sectional view of a cross section corresponding to the A-A cross section of FIG. 1 in a MEMS device according to a second example embodiment of the present invention. The MEMS device 10A according to the second example embodiment is different from the MEMS device 10 according to the first example embodiment in including an insulating layer 44. The differences from the first example embodiment will be described hereinafter. The components of the MEMS device 10A that are identical to those of the MEMS device 10 according to the first example embodiment are given the same reference numerals. The description thereof will basically be omitted and will be given if necessary.

The MEMS device 10A includes the insulating layer 44. The insulating layer 44 is an example of a second insulating layer.

In the second example embodiment, the insulating layer 44 is preferably positioned between the second metal layer 42 and the major surface 30A of the second substrate 30. That is, the insulating layer 44 is provided on the second metal layer 42. In other words, the insulating layer 44 is provided on the major surface 30A of the second substrate 30. In the second example embodiment, the insulating layer 44 is at the same or substantially the same position in the opposing direction 100 as the insulating layers 52. The insulating layer 44 may be at or substantially at the same position in the opposing direction 100 as the insulating layers 52. The insulating layer 44 may be at a position different from the insulating layers 52 in the opposing direction 100. For example, the insulating layer 44 may be provided on the major surface 30A while the insulating layers 52 are provided on the major surface 20A.

The insulating layer 44 is made of an insulator that is electrically insulated. In the second example embodiment, for example, the insulating layer 44 is made of the same material (for example, silicon dioxide (SiO₂)) as the insulating layers 52. The first substrate 20 and the second substrate 30 are thus electrically insulated from each other. The insulating layer 44 may be made of a material different from the insulating layers 52.

The insulating layer 44 is preferably positioned between the second metal layer 42 and the major surface 30A of the second substrate 30 as described above. However, the position of the insulating layer 44 in the opposing direction 100 is not limited to between the second metal layer 42 and the major surface 30A of the second substrate 30. For example, the insulating layer 44 may be positioned between the first metal layer 41 and the major surface 20A of the first substrate 20. That is, the insulating layer 44 may be at a position different from the insulating layers 52 in the opposing direction 100. Furthermore, for example, the insulating layer 44 may be positioned between the second metal layer 42 and the major surface 30A of the second substrate 30, and may be also positioned between the first metal layer 41 and the major surface 20A of the first substrate 20.

If insulating layers are provided only on the contact layers 51, among the contact layers 51 and the first joint portion 40, there could be a height difference between the first joint portion 40 and the contact layers 51 equivalent to the height of the insulating layers in the manufacturing process of the MEMS device 10. According to the second example embodiment, insulating layers are provided on both the first joint portion 40 and the contact layers 51. This can make the height difference between the first joint portion 40 and the contact layers 51 smaller in the manufacturing process of the MEMS device 10. Therefore, the control of the interval between the first substrate 20 and the second substrate 30 by the formation of the contact layers 51 can be easily performed with high accuracy.

In an example of a method of manufacturing the MEMS device 10A according to the second example embodiment, the insulating layers 44 and 52 are formed on the major surface 30A of the second substrate 30 in the insulating layer formation step.

The insulating layer 44 is preferably defined in a region that corresponds to the first metal layer 41 and the second metal layer 42 when the major surface 30A of the second substrate 30 is located opposite to the major surface 20A of the first substrate 20 in the opposing direction 100 in the joint step. The insulating layer 44 thus overlaps the first metal layer 41 and the second metal layer 42 as viewed in the opposing direction 100 when the major surface 30A of the second substrate 30 is located opposite to the major surface 20A of the first substrate 20 in the opposing direction 100 in the joint step.

The insulating layers 52 are formed in regions that correspond to the respective contact layers 51 when the major surface 30A of the second substrate 30 is located opposite to the major surface 20A of the first substrate 20 in the opposing direction 100 in the joint step. The insulating layers 52 thus overlap the contact layers 51 as viewed in the opposing direction 100 when the major surface 30A of the second substrate 30 is located opposite to the major surface 20A of the first substrate 20 in the opposing direction 100 in the joint step. The insulating layers 52 are an example of the first insulating layer.

When the insulating layer 44 is provided on the major surface 30A of the second substrate 30 like this manufacturing example, the second metal layer 42 is provided on the major surface 30A of the second substrate 30 with the insulating layer 44 interposed therebetween in the second metal layer formation step.

When the insulating layer 44 is formed on the major surface 20A of the first substrate 20 unlike this manufacturing example, the first metal layer 41 is provided on the major surface 20A of the first substrate 20 with the insulating layer 44 interposed therebetween in the first metal layer formation step. Furthermore, when the insulating layer 44 is formed on both the major surfaces 20A and 30A, the first metal layer 41 is formed on the major surface 20A of the first substrate 20 with one of the insulating layers 44 interposed therebetween in the first metal layer formation step, and the second metal layer 42 is formed on the major surface 30A of the second substrate 30 with the other insulating layer 44 interposed therebetween in the second metal layer formation step.

The contact layers 51 are formed in the same or substantially the same manner as the manufacturing method of the MEMS device 10 according to the first example embodiment.

The insulating layer 44 and the insulating layers 52 may be formed in separate steps. For example, the insulating layer 44 and the insulating layers 52 are formed in separate steps when the insulating layer 44 is composed of a material different from the insulating layers 52. Furthermore, for example, the insulating layer 44 and the insulating layers 52 are formed in separate steps when the insulating layer 44 is formed at a position different from the insulating layers 52 (for example, when the insulating layer 44 is formed on the major surface 30A of the second substrate 30 while the insulating layers 52 are formed on the major surface 20A of the first substrate 20).

According to this manufacturing method, the insulating layers are formed both at the position corresponding to the first metal layer 41 and the second metal layer 42 and at the positions corresponding to the contact layers 51. This can make the height difference between these positions smaller. Therefore, the control of the interval between the first substrate 20 and the second substrate 30 by the formation of the contact layers 51 can be easily performed with high accuracy.

### Third Example Embodiment

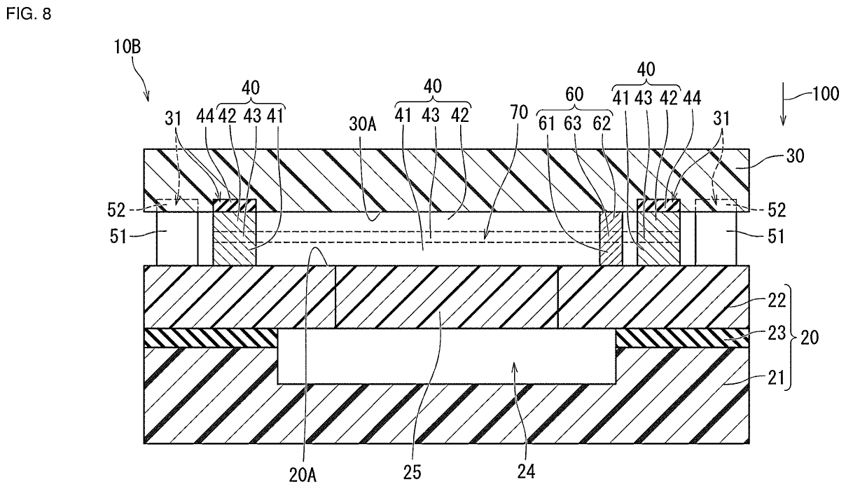

FIG. 8 is a cross-sectional view of a cross section corresponding to the A-A cross section of FIG. 1 in a MEMS device according to a third example embodiment of the present invention. A MEMS device 10B according to the third example embodiment is different from the MEMS device 10A according to the second example embodiment in that the insulating layers 44 and 52 are embedded in the second substrate 30. Hereinafter the differences from the second example embodiment will be described. The components of the MEMS device 10B that are identical to those of the MEMS device 10A according to the second example embodiment are given the same reference numerals. The description thereof will basically be omitted and will be given necessary.

In the MEMS device 10B, recesses 31 are provided in the major surface 30A of the second substrate 30. The recesses 31 are provided in regions corresponding to the insulating layers 44 and 52. In the recesses 31, the insulating layers 44 and 52 are embedded. That is, the insulating layers 44 and 52 are embedded in the second substrate 30.

The insulating layers 44 and 52 may be embedded in the first substrate 20. In this case, the recesses 31 are provided in the major surface 20A of the first substrate 20. Either the insulating layer 44 or the insulating layers 52 may be embedded in the first substrate 20 while the other is embedded in the second substrate 30. In this case, the recesses 31 are provided in the major surface 20A of the first substrate 20 and the major surface 30A of the second substrate 30. The insulating layers 44 and 52 may be embedded in both the first substrate 20 and the second substrate 30.

In the MEMS device 10 according to the first example embodiment not including the insulating layers 52, the insulating layer 44 may be embedded. In this case, the insulating layer 44 is embedded in at least one of the first substrate 20 and the second substrate 30.

According to the third example embodiment, the contact surfaces between the insulating layers 52 and the contact layers 51 can be flush with the first and second substrates 20 and 30 with the insulating layers 52 embedded. Therefore, the control of the interval between the first substrate 20 and the second substrate 30 by the contact layers 51 can be easily performed with high accuracy.

According to the third example embodiment, the contact surface between the insulating layer 44 and the first joint portion 40 and the contact surfaces between the insulating layers 52 and the contact layers 51 can be flush with the first and second substrates 20 and 30 with the insulating layers embedded. Therefore, the control of the interval between the first substrate 20 and the second substrate 30 by the contact layers 51 can be easily performed with high accuracy.

In an example of a manufacturing method of the MEMS device 10B according to the third example embodiment, a recess formation step is executed before the insulating layer formation step.

In the recess formation step, the recesses 31 are formed in regions of the major surface 30A of the second substrate 30 where the insulating layers 44 and 52 are to be formed.

In the insulating layer formation step executed after the recess formation step, the recesses 31 are filled with paste made of the materials (for example, preferably silicon dioxide, for example) of the insulating layers 44 and 52.

Then the second metal layer formation step is executed. The second metal layer 42 is formed on the major surface 30A of the second substrate 30 with the insulating layer 44 interposed therebetween.

In the case of forming the insulating layers 44 and 52 on the first substrate 20, in the recess formation step, the recesses are formed in regions of the major surface 20A of the first substrate 20 where the insulating layers 44 and 52 are to be formed. In the case of forming the insulating layers 44 and 52 on the first substrate 20 and the second substrate 30, in the recess formation step, the recesses are formed in regions of the major surface 20A of the first substrate 20 and the major surface 30A of the second substrate 30 where the insulating layers 44 and 52 are to be formed. That is, the recesses are formed in at least one of the major surface 20A of the first substrate 20 and the major surface 30A of the second substrate 30.

According to this manufacturing method, the insulating layers 44 and 52 can be formed so as not to protrude from the major surface 20A of the first substrate 20 and the major surface 30A of the second substrate 30. For example, the insulating layers 44 and 52 can be formed so as to be flush with the major surface 20A of the first substrate 20 and the major surface 30A of the second substrate 30. Therefore, the control of the interval between the first substrate 20 and the second substrate 30 by the formation of the contact layers 51 can be easily performed with high accuracy.

### Fourth Example Embodiment

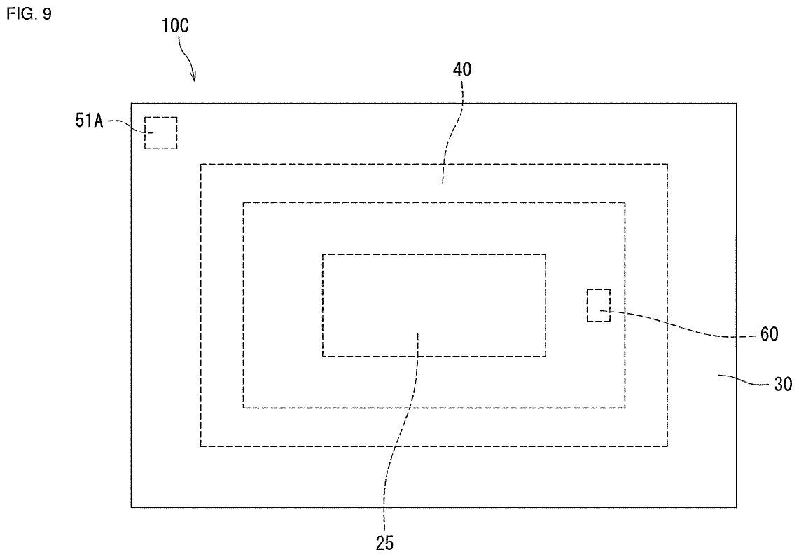

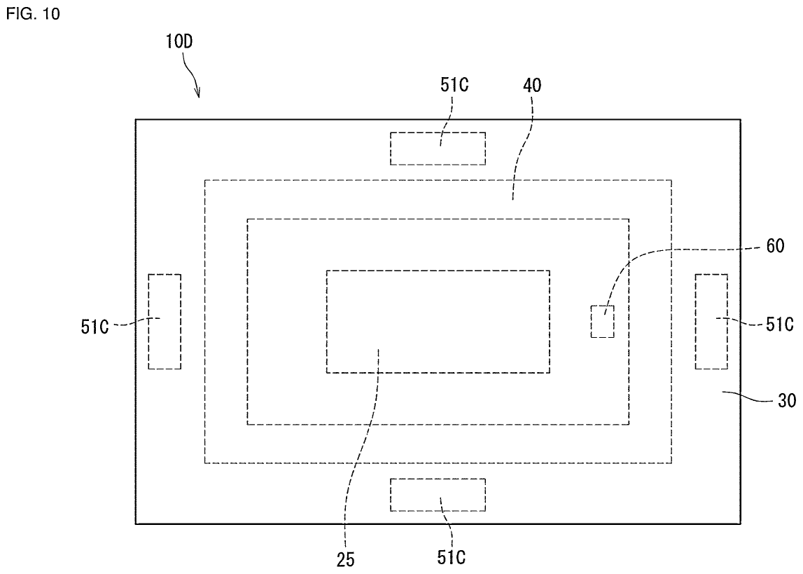

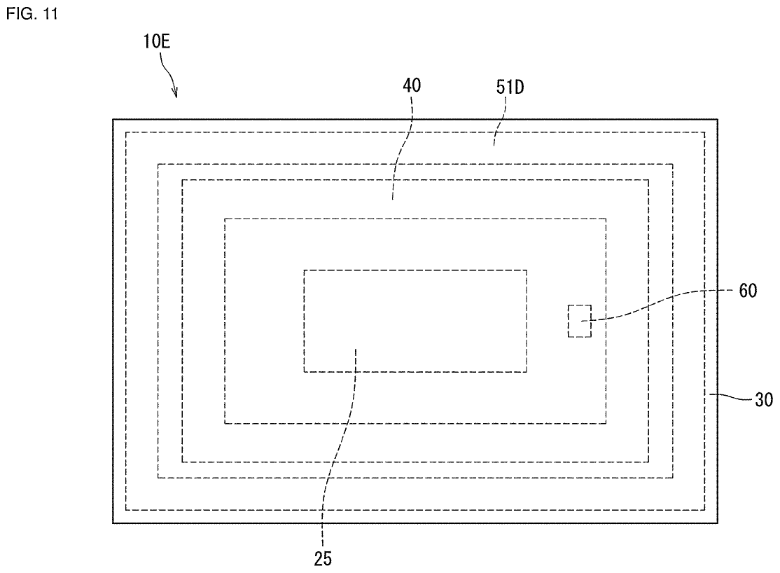

FIG. 9 is a plan view of a MEMS device according to a fourth example embodiment of the present invention. FIG. 10 is a plan view of another MEMS device according to the fourth example embodiment of the present invention. FIG. 11 is a plan view of still another MEMS device according to the fourth example embodiment of the present invention. MEMS devices 10C, 10D, and 10E according to the fourth example embodiment are different from the MEMS device 10 according to the first example embodiment in terms of the number, shape, size, and arrangement of the contact layers 51. Hereinafter, the differences from the first example embodiment will be described. The components of the MEMS device 10C, 10D, and 10E that are identical to those of the MEMS device 10 according to the first example embodiment are given the same reference numerals. The description thereof will basically be omitted and will be given if necessary.

As illustrated in FIG. 1, the MEMS device 10 according to the first example embodiment preferably includes the four contact layers 51. The four contact layers 51 are positioned adjacent the respective four vertices of the first joint portion 40, which has a rectangular shape as viewed in the opposing direction 100. Each of the four contact layers 51 is L-shaped as viewed in the opposing direction 100. However, the number, shape, size, and arrangement of the contact layers 51 are not limited to those described above.

For example, the MEMS device 10C illustrated in FIG. 9 includes a single contact layer 51A. The contact layer 51A is positioned adjacent one of the four vertices of the first joint portion 40, which has a rectangular shape as viewed in the opposing direction 100. The contact layer 51A is square as viewed in the opposing direction 100.

Furthermore, for example, the MEMS device 10D illustrated in FIG. 10 includes four contact layers 51C. The four contact layers 51C are positioned adjacent the respective four sides of the first joint portion 40, which has a rectangular shape as viewed in the opposing direction 100. Each of the four contact layers 51C is rectangular as viewed in the opposing direction 100.

Still furthermore, for example, the MEMS device 10E illustrated in FIG. 11 includes a single contact layer 51D. The contact layer 51D surrounds the first joint portion 40 and the MEMS structure 25 of the first substrate 20 as viewed in the opposing direction 100.

According to the configuration illustrated in FIG. 11, the contact layer 51D surrounds the MEMS structure 25 as viewed in the opposing direction 100. The contact layer 51D thus has a large area as viewed in the opposing direction 100. Furthermore, the distances between the first joint portion 40 and the contact layer 51D at all locations can be substantially equal. Therefore, the control of the interval between the first substrate 20 and the second substrate 30 by the formation of the contact layer 51D can be easily performed with high accuracy.

### Fifth Example Embodiment

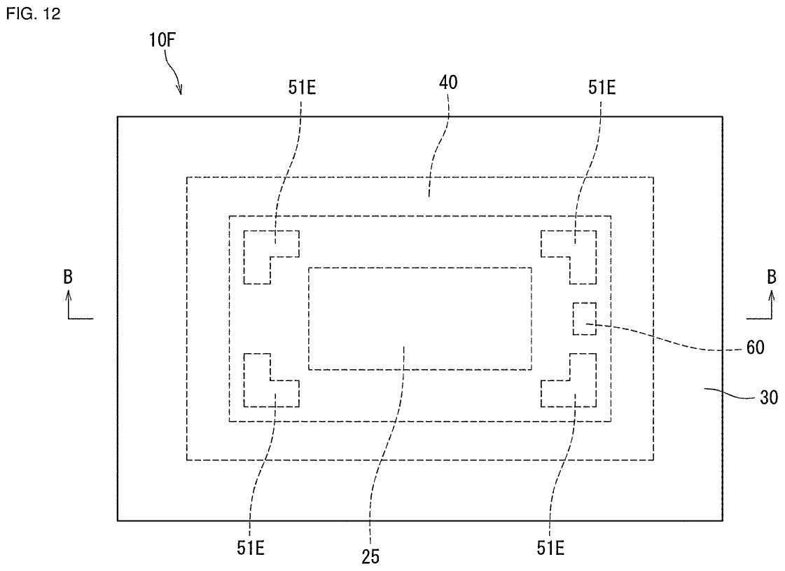

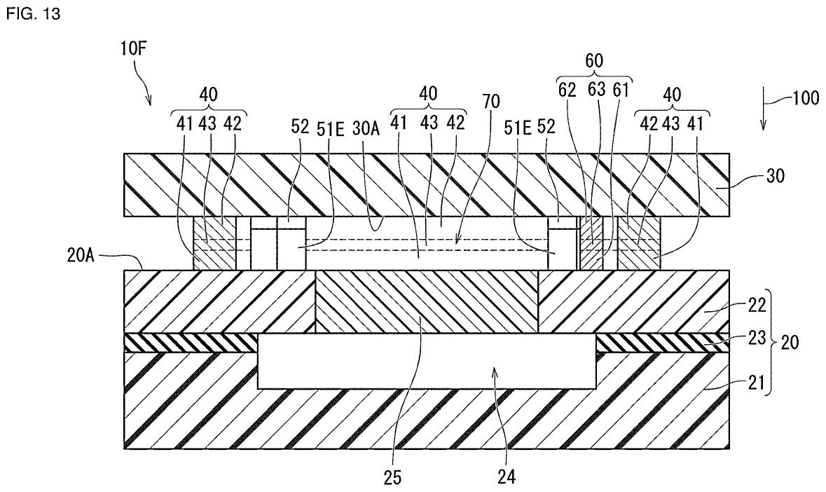

FIG. 12 is a plan view of a MEMS device according to a fifth example embodiment of the present invention. FIG. 13 is a cross-sectional view of a B-B cross section of FIG. 12. A MEMS device 10F according to the fifth example embodiment is different from the MEMS device 10 according to the first example embodiment in that contact layers 51E are positioned inside the first joint portion 40 as viewed in the opposing direction 100. Hereinafter, the differences from the first example embodiment will be described. The components of the MEMS device 10F that are identical to those of the MEMS device 10 according to the first example embodiment are given the same reference numerals. The description thereof will basically be omitted and will be given if necessary.

As illustrated in FIGS. 12 and 13, the contact layers 51E are positioned inside the first joint portion 40 as viewed in the opposing direction 100. In the fifth example embodiment, the MEMS device 10F includes the four contact layers 51E. The four contact layers 51E are positioned adjacent the respective four vertices of the first joint portion 40, which has a rectangular shape as viewed in the opposing direction 100. The second joint portion 60 is disposed in a region inside the first joint portion 40 on the major surface 20A of the first substrate 20, other than the MEMS structure 25 and the contact layers 51E.

According to the fifth example embodiment, the contact layers 51E are positioned inside the first joint portion 40 as viewed in the opposing direction 100. Therefore, the MEMS device 10 can be reduced in size compared to a configuration in which the contact layers 51E are positioned outside the first joint portion 40 as viewed in the opposing direction 100.

### Sixth Example Embodiment

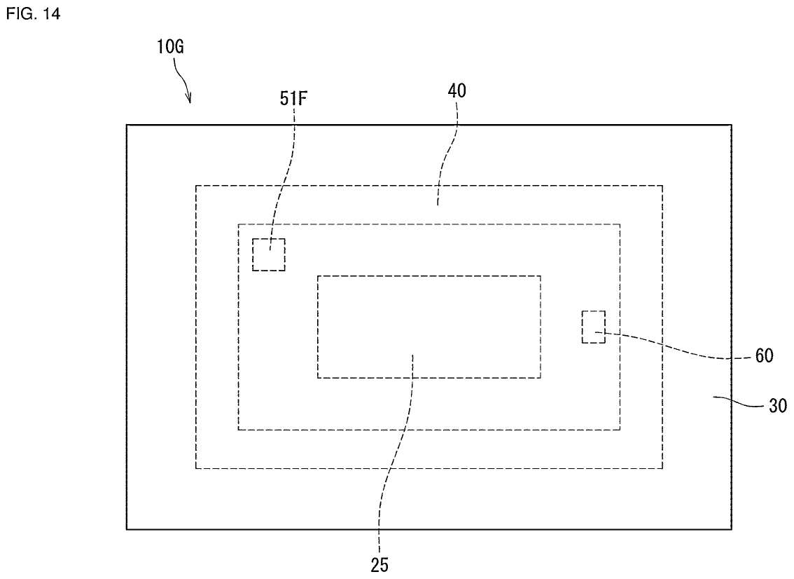

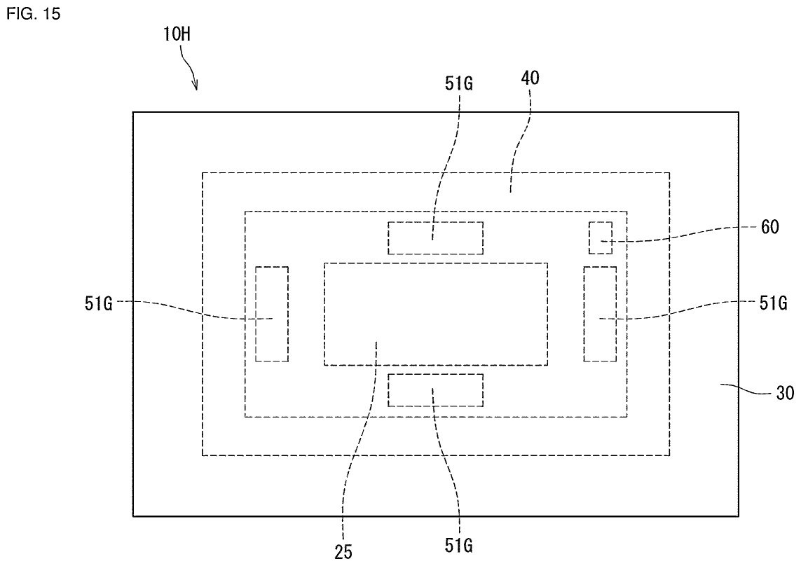

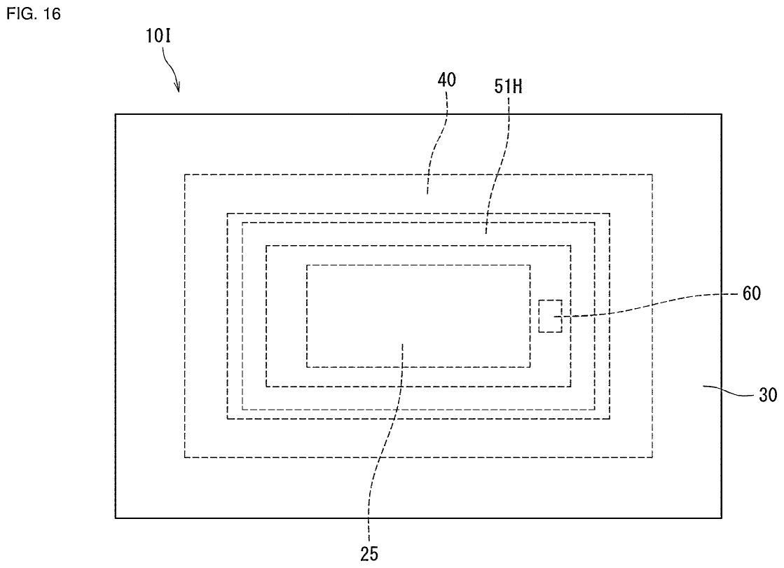

FIG. 14 is a plan view of a MEMS device according to a sixth example embodiment of the present invention. FIG. 15 is a plan view of another MEMS device according to the sixth example embodiment of the present invention. FIG. 16 is a plan view of still another MEMS device according to the sixth example embodiment of the present invention. MEMS devices 10G, 10H, and 10I according to the sixth example embodiment are different from the MEMS device 10F according to the fifth example embodiment in the number, shape, size, and arrangement of the contact layers 51F. Hereinafter, the differences from the fifth example embodiment will be described. The components of the MEMS device 10G, 10H, and 10I that are identical to those of the MEMS device 10F according to the fifth example embodiment are given the same reference numerals. The description thereof will basically be omitted and will be described if necessary.

As illustrated in FIG. 12, the MEMS device 10F according to the fifth example embodiment includes the four contact layers 51E. The four contact layers 51E are positioned adjacent the respective four vertices of the first joint portion 40, which has a rectangular shape as viewed in the opposing direction 100. Each of the four contact layers 51E is L-shaped as viewed in the opposing direction 100. However, the number, shape, size, and arrangement of the contact layers 51 are not limited to those described above.

For example, the MEMS device 10G illustrated in FIG. 14 preferably includes a single contact layer 51F. The contact layer 51F is positioned adjacent one of the four vertices of the first joint portion 40, which has a rectangular shape as viewed in the opposing direction 100. The contact layer 51F is square as viewed in the opposing direction 100.

Furthermore, for example, the MEMS device 10H illustrated in FIG. 15 includes four contact layers 51G. The four contact layers 51G are positioned adjacent the respective four sides of the first joint portion 40, which has a rectangular shape as viewed in the opposing direction 100. Each of the four contact layers 51G is rectangular as viewed in the opposing direction 100.

Still furthermore, for example, the MEMS device 10I illustrated in FIG. 16 includes a single contact layer 51H. The contact layer 51H surrounds the second joint portion 60 and the MEMS structure 25 in the first substrate 20 as viewed in the opposing direction 100. The contact layer 51H does not need to surround the second joint portion 60. In this case, the second joint portion 60 is positioned between the contact layer 51H and the first joint portion 40 as viewed in the opposing direction 100.

### Seventh Example Embodiment

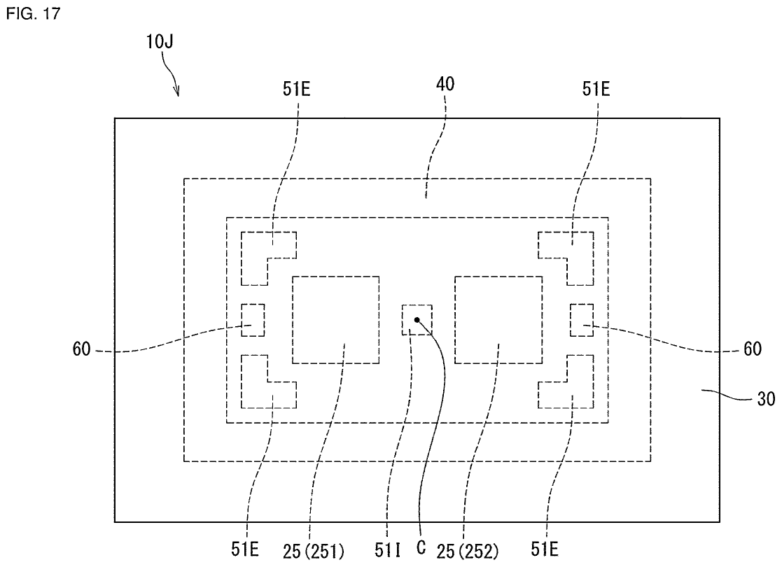

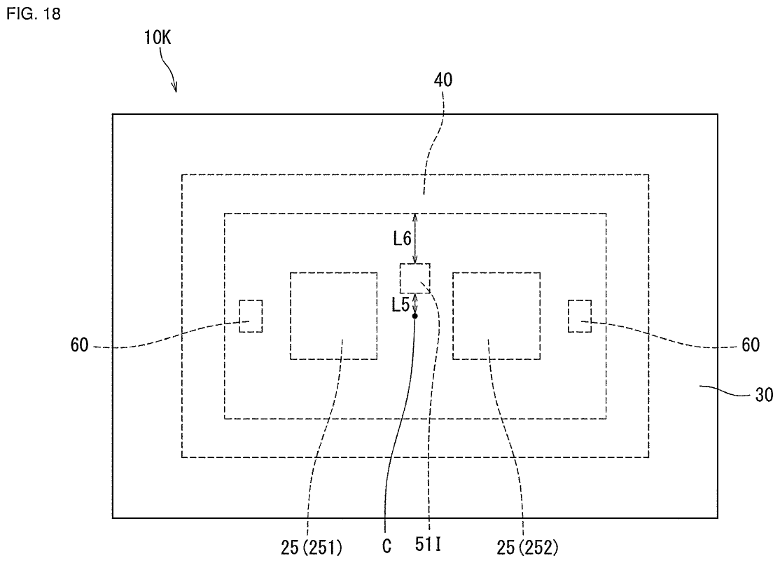

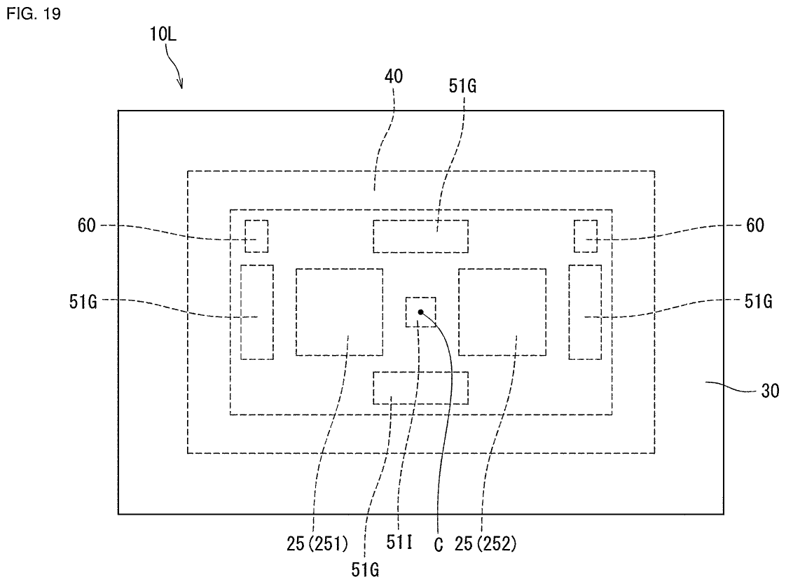

FIG. 17 is a plan view of a MEMS device according to a seventh example embodiment of the present invention. FIG. 18 is a plan view of another MEMS device according to the seventh example embodiment of the present invention. FIG. 19 is a plan view of still another MEMS device according to the seventh example embodiment of the present invention. MEMS devices 10J, 10K, and 10L according to the seventh example embodiment are different from the MEMS device 10F according to the fifth example embodiment in including a plurality of MEMS structures 25. Hereinafter, the differences from the fifth example embodiment will be described. The components of the MEMS device 10J, 10K, and 10L that are identical to those of the MEMS device 10F according to the fifth example embodiment are given the same reference numerals. The description thereof will basically be omitted and will be described if necessary.

MEMS devices may include plural MEMS structures 25. As illustrated in FIGS. 17 to 19, in each of the MEMS devices 10J, 10K, and 10L, the upper layer 22 includes two MEMS structures 251 and 252. The upper layer 22 may include three or more MEMS structures 25.

As illustrated in FIG. 17, the MEMS device 10J includes four contact layers 51E, one contact layer 51I, and two second joint portions 60.

As illustrated in FIG. 18, the MEMS device 10K includes one contact layer 51I and two second joint portions 60.

As illustrated in FIG. 19, the MEMS device 10L includes four contact layers 51G, one contact layer 51I, and two second joint portions 60.

In FIGS. 17 to 19, the contact layer 51I is positioned between the two MEMS structures 251 and 252, and the two second joint portions 60 are electrically coupled to the respective two MEMS structures 25.

As illustrated in FIG. 18, distance L5 between the center C and the contact layer 51I is shorter than distance L6 between the first joint portion 40 and the contact layer 51I as viewed in the opposing direction 100. The center C is the center of rotational symmetry of the region surrounded by the first joint portion 40. The distance L5 is the shortest distance between the center C and the contact layer 51I. The distance L6 is the shortest distance between the first joint portion 40 and the contact layer 51I. Herein, the region surrounded by the first joint portion 40 is rectangular and is rotationally symmetric. The region surrounded by the first joint portion 40 needs to be rotationally symmetric and is not limited to being rectangular. For example, the region surrounded by the first joint portion 40 may be circular.

In FIGS. 17 and 19, the contact layer 51I overlaps the center C as viewed in the opposing direction 100. In this case, the distance L5 is zero. Therefore, the distance L5 is shorter than the distance L6 even in FIGS. 17 and 19.

When the center C of rotational symmetry of the region surrounded by the first joint portion 40 is distant from the first joint portion as viewed in the opposing direction 100, the first and second substrates 20 and 30 are more likely to bend at the center C.

According to the seventh example embodiment, the contact layers 51 are positioned adjacent the center C of rotational symmetry in the region surrounded by the first joint portion 40 as viewed in the opposing direction 100. This can prevent the first substrate 20 and the second substrate 30 from bending at the center C.

In the example explained with FIGS. 17 to 19, the contact layers 51 are positioned inside the first joint portion 40 as viewed in the opposing direction 100. However, in configuration in which the MEMS device includes plural MEMS structures 25, the contact layers 51 may be positioned outside the first joint portion 40 like the first to fourth example embodiments.

### Eighth Example Embodiment

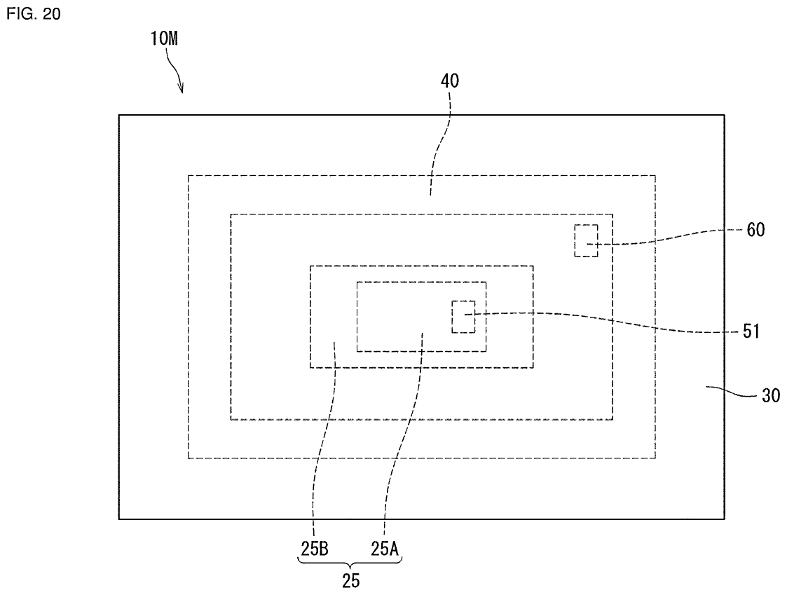

FIG. 20 is a plan view of a MEMS device according to an eighth example embodiment of the present invention. A MEMS device 10M according to the eighth example embodiment is different from the MEMS device 10 according to the first example embodiment in that the contact layer 51 is disposed on the fixed portion 25A. Hereinafter, the differences from the first example embodiment will be described. The components of the MEMS device 10M that are identical to those of the MEMS device 10 according to the first example embodiment are given the same reference numerals. The description thereof will basically be omitted and will be described if necessary. FIGS. 1 and 2 and other drawings of the first example embodiment do not distinctly illustrate the fixed portion and the moving portion, but FIG. 20 of the eighth example embodiment distinctly illustrates a fixed portion 25A and a moving portion 25B.

As illustrated in FIG. 20, the MEMS structure 25 includes the fixed portion 25A and the moving portion 25B. The fixed portion 25A is fixed to the upper layer 22 of the first substrate 20 and does not move relative to the upper layer 22. The moving portion 25B is coupled to the fixed portion 25A and is flexible relative to the fixed portion 25A. That is, the moving portion 25B moves relative to the fixed portion 25A. The contact layer 51 is disposed on the fixed portion 25A of the MEMS structure 25 as viewed in the opposing direction 100. That is, the contact layer 51 is coupled to the fixed portion 25A as viewed in the opposing direction 100.

According to the eighth example embodiment, the contact layer 51 is in contact with the MEMS structure 25. The second substrate 30, therefore, does not need to include a region for the contact layer 51 to come into contact with, other than the MEMS structure 25. This can reduce the MEMS device 10M in size.

According to the eighth example embodiment, the contact layer 51 is joined to the fixed portion 25A of the MEMS structure 25. Therefore, the contact layer 51 cannot inhibit the vibration of the MEMS structure 25.

### Ninth Example Embodiment

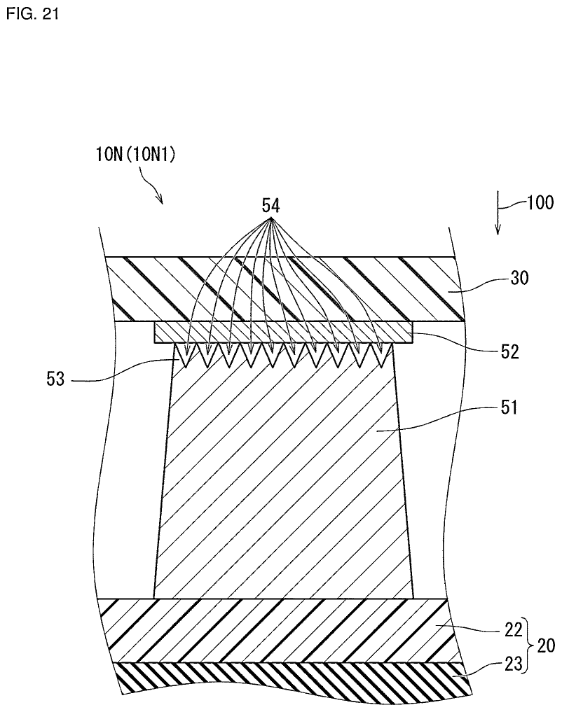

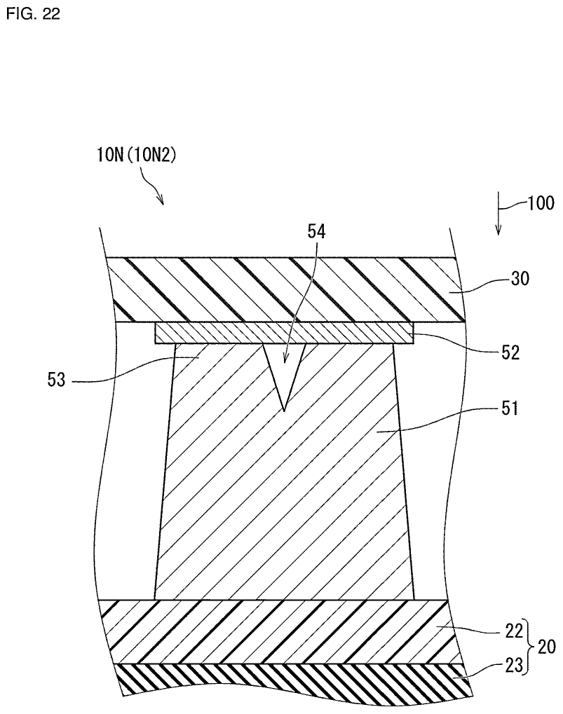

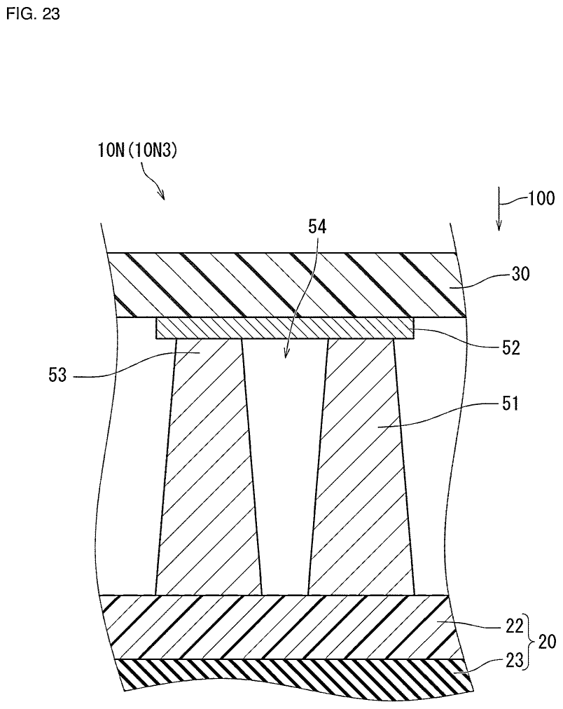

FIG. 21 is a cross-sectional view of the contact layer and the vicinity thereof in a MEMS device according to a ninth example embodiment of the present invention. FIG. 22 is a cross-sectional view of the contact layer and the vicinity thereof in another MEMS device according to the ninth example embodiment of the present invention. FIG. 23 is a cross-sectional view of the contact layer and the vicinity thereof in still another MEMS device according to the ninth example embodiment of the present invention. A MEMS device 10N according to the ninth example embodiment is different from the MEMS device 10 according to the first example embodiment in that cavities are defined in the interface between an insulating layer and a contact layer. Hereinafter, the differences from the first example embodiment will be described. The components of the MEMS device 10N that are identical to those of the MEMS device 10 according to the first example embodiment are given the same reference numerals. The description thereof will basically be omitted and will be described if necessary.

In the MEMS device 10 according to the first example embodiment, as illustrated in FIG. 2, the insulating layers 52 are in surface contact with the contact layers 51, and there are no gaps formed between the insulating layers 52 and the contact layers 51. However, gaps may be formed between the insulating layers 52 and the contact layers 51.

For example, as illustrated in FIGS. 21 to 23, cavities 54 are defined in an interface 53 between the insulating layer 52 and the contact layer 51. In a MEMS device 10N1 illustrated in FIG. 21, plural cavities 54 are formed. In a MEMS device 10N2 illustrated in FIG. 22, a single cavity 54 is formed. In a MEMS device 10N3 illustrated in FIG. 23, a cavity 54 penetrates the contact layer 51 in the opposing direction 100.

The number, shape, position, and size of the cavities 54 are not limited to the number, shape, position, and size illustrated in FIGS. 21 to 23. In FIG. 21, the cavities 54 are arranged closely. However, there may be a region not including any cavity 54 between adjacent cavities 54.

When the cavities 54 are not provided in the interface 53 between the insulating layer 52 and the contact layer 51, the insulating layer 52 and contact layer 51 of the second joint portion 50 are in contact over a large area. In this case, the contact layer 51 is more likely to be crushed and deformed by the insulating layer 52 at high temperature under high load in the manufacturing process of the MEMS device 10. According to the ninth example embodiment, the cavities 54 are preferably provided in the interface 53 between the insulating layer 52 and the contact layer 51, so that the insulating layer 52 and the contact layer 51 are in contact over a small area. The contact layer 51 is therefore less likely to be deformed at high temperature under high load in the manufacturing process of the MEMS device 10.

By properly combining any of the aforementioned various example embodiments, the effects thereof can be exerted.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A MEMS device, comprising:
a first substrate including a MEMS structure;
a second substrate opposing the first substrate with an interval therebetween in an opposing direction;
a first joint portion including a eutectic layer including as a main material, a eutectic alloy of a plurality of types of metal, provided between the first substrate and the second substrate and surrounding the MEMS structure as viewed in the opposing direction, and joined to the first substrate and the second substrate; and
a contact layer between the first substrate and the second substrate, directly or indirectly in contact with the first substrate, and directly or indirectly in contact with the second substrate; wherein
the contact layer includes a portion of the plurality of types of metal included in the first joint portion.

2. The MEMS device according to claim 1, wherein a length of the first joint portion in the opposing direction is greater than or equal to a length of the contact layer in the opposing direction.

3. The MEMS device according to claim 1, further comprising a second joint portion including a eutectic layer including as a main material, the eutectic alloy of the plurality of types of metal, positioned inside the first joint portion as viewed in the opposing direction between the first substrate and the second substrate, and joined to the first substrate and the second substrate.

4. The MEMS device according to claim 3, wherein the second joint portion includes at least a portion of materials included in the first substrate and the second substrate.

5. The MEMS device according to claim 1, further comprising a first insulating layer on the contact layer and being electrically insulated.

6. The MEMS device according to claim 5, wherein the first insulating layer is embedded in at least one of the first substrate and the second substrate.

7. The MEMS device according to claim 5, further comprising:
a second insulating layer on the first joint portion and being electrically insulated; wherein
the second insulating layer is provided at a same position or substantially the same position in the opposing direction as the first insulating layer.

8. The MEMS device according to claim 7, wherein the first insulating layer and the second insulating layer are embedded in at least one of the first substrate and the second substrate.

9. The MEMS device according to claim 5, wherein a cavity is provided in an interface between the first insulating layer and the contact layer.

10. The MEMS device according to claim 1, wherein the contact layer is positioned inside the first joint portion as viewed in the opposing direction.

11. The MEMS device according to claim 10, wherein
the MEMS structure includes:
a fixed portion fixed to the first substrate; and
a moving portion flexible relative to the first substrate; and
the contact layer is in contact with the fixed portion as viewed in the opposing direction.

12. The MEMS device according to claim 10, wherein
a region surrounded by the first joint portion is rotationally symmetric when viewed in the opposing direction; and
when viewed in the opposing direction, a distance between a center of rotational symmetry of the region surrounded by the first joint portion and the contact layer is shorter than a distance between the first joint portion and the contact layer.

13. The MEMS device according to claim 1, wherein the contact layer surrounds the MEMS structure as viewed in the opposing direction.

14. The MEMS device according to claim 1, wherein a distance between the first joint portion and the contact layer is less than or equal to about 1 mm and greater than or equal to 0 mm as viewed in the opposing direction.

15. The MEMS device according to claim 1, wherein an area of the contact layer is greater than or equal to about 8% of an area of the first joint portion and is less than or equal to an area of the first substrate excluding a region overlapping the first joint portion as viewed in the opposing direction.

16. A method of manufacturing a MEMS device, comprising:
a first metal layer formation step of forming on a major surface of a first substrate including a MEMS structure, a first metal layer including a first type of metal and surrounding the MEMS structure;
a second metal layer formation step of forming in a region corresponding to the first metal layer on a major surface of a second substrate, a second metal layer including a second type of metal that is able to undergo a metal eutectic reaction with the first type of metal;
a contact layer formation step of forming on the major surface of the first substrate or the major surface of the second substrate, a contact layer including one of the first type of metal and the second type of metal; and
a joint step of, after executing the first metal layer formation step, the second metal layer formation step, and the contact layer formation step, arranging the major surface of the first substrate and the major surface of the second substrate opposite to each other in an opposing direction and bringing the first substrate and the second substrate close to each other until the contact layer comes into contact with the major surface of the first substrate and the major surface of the second substrate to cause the first metal layer and the second metal layer to undergo a metal eutectic reaction.

17. The method of manufacturing a MEMS device according to claim 16, wherein a total length of the first metal layer and the second metal layer in the opposing direction is greater than a length of the contact layer in the opposing direction.

18. The method of manufacturing a MEMS device according to claim 16, wherein
in the first metal layer formation step, a third metal layer including the first type of metal is defined inside the first metal layer on the major surface of the first substrate;
in the second metal layer formation step, a fourth metal layer including the second type of metal is defined in a region corresponding to the third metal layer on the major surface of the second substrate; and
in the joint step, the third metal layer and the fourth metal layer undergo a metal eutectic reaction.

19. The method of manufacturing a MEMS device according to claim 18, wherein at least one of the third metal layer and the fourth metal layer includes at least a portion of materials defining the first substrate or the second substrate that is adjacent to the at least one of the third metal layer and the fourth metal layer.

20. The method of manufacturing a MEMS device according to claim 16, further comprising:
an insulating layer formation step of forming an insulating layer electrically insulated, on at least one of the major surface of the first substrate and the major surface of the second substrate; wherein
in the contact layer formation step, the contact layer is provided on the insulating layer provided on at least one of the major surface of the first substrate and the major surface of the second substrate or in a region corresponding to the insulating layer on the major surface of the first substrate or the major surface of the second substrate.

21. The method of manufacturing a MEMS device according to claim 20, wherein
the insulating layer defined in the insulating layer formation step includes:
a first insulating layer overlapping the contact layer as viewed in the opposing direction when the major surface of the first substrate and the major surface of the second substrate are arranged opposite to each other in the opposing direction in the joint step; and
a second insulating layer overlapping the first metal layer and the second metal layer as viewed in the opposing direction when the major surface of the first substrate and the major surface of the second substrate are arranged opposite to each other in the opposing direction in the joint step;
when the insulating layer is provided on the major surface of the first substrate, the first metal layer is provided on the major surface of the first substrate with the second insulating layer interposed therebetween in the first metal layer formation step;
when the insulating layer is provided on the major surface of the second substrate, the second metal layer is provided on the major surface of the second substrate with the second insulating layer interposed therebetween in the second metal layer formation step; and
in the contact layer formation step, the contact layer is provided on the first insulating layer provided on at least one of the major surface of the first substrate and the major surface of the second substrate or in a region corresponding to the first insulating layer on the major surface of the first substrate or the major surface of the second substrate.

22. The method of manufacturing a MEMS device according to claim 20, further comprising:
a recess formation step of forming a recess in the major surface of the first substrate or the major surface of the second substrate; wherein
in the insulating layer formation step, the insulating layer is formed by filling the recess.
